(19) United States
(12) Patent Application Publication
(10) Pub. No.: US 2026/0148769 A1
(43) Pub. Date: May 28, 2026

(54) NON-VOLATILE MEMORY DEVICE HAVING SPECIAL FUNCTION WORD LINE AND MANAGEMENT METHOD THEREOF

(71) Applicant: Samsung Electronics Co., Ltd., Suwon-si (KR)

(72) Inventors: JI-SANG LEE, Suwon-si (KR); HYUNKOOK PARK, Suwon-si (KR)

(21) Appl. No.: 19/395,996

(22) Filed: Nov. 20, 2025

(30) Foreign Application Priority Data
Nov. 26, 2024 (KR) 10-2024-0171039

(51) Int. Cl. G11C 16/10; G11C 16/04; G11C 16/08; G11C 16/16

(52) U.S. Cl. CPC G11C 16/10; G11C 16/0483; G11C 16/08; G11C 16/16

(57) ABSTRACT

A management method of a special function word line of a non-volatile memory device comprises receiving a program command, checking a threshold voltage level of special function memory cells connected to the special function word line when memory cells selected according to the program command correspond to a specific word line, programming the special function memory cells with a predetermined pattern according to a check result of the threshold voltage level, and programming the memory cells selected according to the program command.

### CROSS-REFERENCE TO RELATED APPLICATIONS

This application claims priority to Korean Patent Application No. 10-2024-0171039 filed in the Korean Intellectual Property Office on November 26, 2024, the disclosure of which is incorporated by reference herein in its entirety.

### BACKGROUND

Semiconductor memory devices can be broadly divided into volatile memory and non-volatile memory. Volatile memory (e.g. DRAM or SRAM) has fast read/write speeds, but stored data disappears when power is cut off. On the other hand, non-volatile memory can maintain stored data even when power is cut off.

In order to increase the integration of non-volatile memory devices, memory cells where user data is not stored can be used as special function word lines such as string selection lines SSLs, ground selection lines GSLs, and dummy word lines..

### SUMMARY

In general, the present disclosure is directed toward a non-volatile memory device capable of maintaining a constant threshold voltage of memory cells coupled to special function word lines in which data is not stored, and a method for managing the same. Memory cells connected to special function word lines should have guaranteed operational reliability. If the operational reliability of memory cells connected to the special function word lines is not guaranteed, data reliability of memory cells located around them may collapse. However, the characteristics of special function word lines may also change over time. The present disclosure provides management techniques for various special function word lines that are not used for data storage purposes.

According to some implementations, the present disclosure is directed to a management method of a special function word line of a non-volatile memory device, comprising, receiving a program command, checking a threshold voltage level of special function memory cells connected to the special function word line when memory cells selected according to the program command correspond to a specific word line, programming the special function memory cells with a predetermined pattern according to a check result of the threshold voltage level, and programming the memory cells selected according to the program command.

According to some implementations, the present disclosure is directed to a non-volatile memory device, comprising, a cell array having a main word line to which main memory cells storing data are connected, and a special function word line to which special function memory cells supporting a selection operation of the main memory cells are connected, a row decoder configured to select the main word line or the special function word line in response to an address, a page buffer connected to the main memory cells or the special function memory cells through a bit line, and a control logic circuit configured to check a threshold voltage level of the special function memory cells in response to selection of a specific word line by a program command, and/or configured to control the row decoder or the page buffer to program the special function memory cells with a predetermined pattern.

According to some implementations, the present disclosure is directed to a management method of a non-volatile memory device, comprising, erasing special function memory cells connected to the special function word line during a block erase operation, receiving a program command, programming the special function memory cells with a predetermined pattern when memory cells selected according to the program command correspond to a specific word line, and programming data requested to be written to the memory cells selected according to the program command.

### BRIEF DESCRIPTION OF THE DRAWINGS

Example implementation will be more clearly understood from the following detailed description, taken in conjunction with the accompanying drawings.

FIG. 1 is a block diagram showing an example of a non-volatile memory device according to some implementations.

FIG. 2 is a block diagram schematically showing an example of a non-volatile memory device according to some implementations.

FIG. 3 is a circuit diagram showing an example of of a memory block constituting the cell array of FIG. 1 according to some implementations.

FIG. 4 is a circuit diagram showing examples of special function word lines of the present invention within the memory block of FIG. 3 according to some implementations.

FIG. 5 is a diagram showing examples of a command sequence and a program sequence according to some implementations.

FIG. 6 is a flowchart showing an example of a method of managing memory cells connected to special function word lines according to some implementations.

FIG. 7 is a flowchart showing an example of a method of managing memory cells connected to special function word lines according to some implementations.

FIG. 8 is a diagram showing an example of a program method of a coded GSL that includes a type of special function word line SFWL according to some implementations.

FIG. 9 is a table showing an example of a pattern code programmed into memory cells of a coded GSL according to some implementations.

FIG. 10 is a flowchart showing an example of a coded GSL management method according to some implementations.

FIG. 11 is a flowchart showing an example of a coded GSL management method according to some implementations.

FIG. 12 is a diagram showing an example of a method of programming dummy word lines that are a type of special function word line SFWL according to some implementations.

FIG. 13 is a flowchart showing an example of a dummy word line management method according to some implementations.

FIG. 14 is a flowchart showing an example of a dummy word line management method according to some implementations.

FIG. 15 is a diagram showing an example of a method of programming center dummy word lines that are a type of special function word line SFWL according to some implementations.

FIG. 16 is a flowchart showing an example of a center dummy word line management method shown in FIG. 15 according to some implementations.

FIG. 17 is a flowchart showing an example of a center dummy word line management method shown in FIG. 15 according to some implementations.

FIG. 18 is a diagram showing an example of a method of managing a programmable string selection line SSL that is one of the special function word lines SFWLs according to some implementations.

FIG. 19 is a flowchart showing an example of a method of managing a string selection line of FIG. 18 according to some implementations.

FIG. 20 is a block diagram showing an examples of a storage system including a non-volatile memory device according to some implementations.

### DETAILED DESCRIPTION

Hereinafter, example implementations will be explained in detail with reference to the accompanying drawings. Reference signs are indicated in detail in implementations of the present disclosure, examples of which are indicated in the reference drawings. Wherever possible, the same reference numbers are used in the description and drawings to refer to the same or like parts.

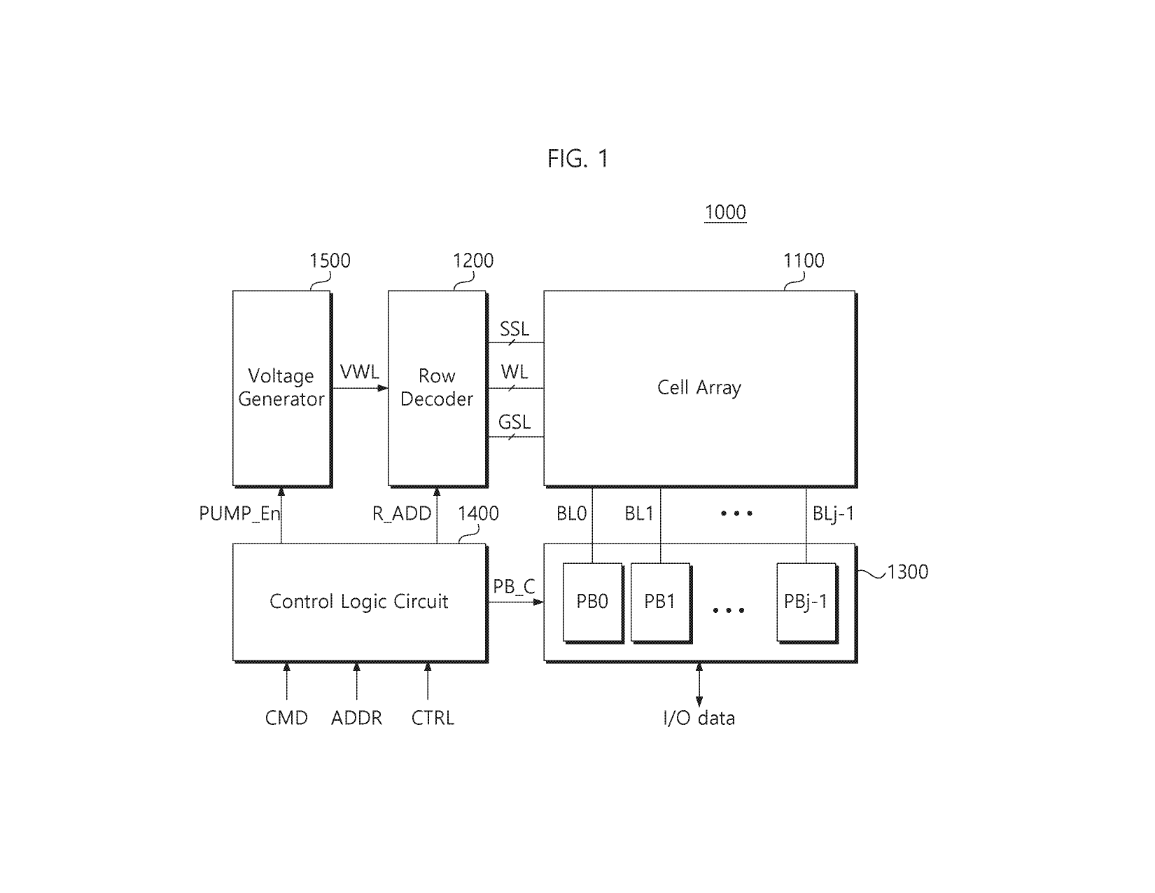

FIG. 1 is a block diagram showing an example of a non-volatile memory device according to some implementations. In FIG. 1, a non-volatile memory device 1000 includes a cell array 1100, a row decoder 1200, a page buffer circuit 1300, a control logic circuit 1400, and a voltage generator 1500.

The cell array 1100 includes a plurality of memory blocks. Each of the plurality of memory blocks may have a three-dimensional structure in which word lines are vertically stacked. Each of the memory blocks may be composed of a plurality of pages. Each page may be composed of a plurality of memory cells. Each memory block may be an erase unit, and each page may be a read or write unit. The cell array 1100 may be formed in a direction perpendicular to the substrate. A gate electrode layer and an insulation layer may be alternately deposited on the substrate.

The cell array 1100 of the present invention may have memory cells for storing data as well as memory cells used for special purposes. For example, a coded ground selection line (below coded GSL) may be a special function word line that performs a GSL function with memory cells programmed with a specific pattern. When data of a specific pattern is programmed into the memory cells of the coded GSL, a function of selecting a string according to the voltage applied to each coded GSL may be provided. In addition, the special function word lines may be expanded to a dummy word line, a center dummy word line, and a programmable string selection line. These special function word lines will be described in more detail through the drawings described below.

In order to implement the above-described special function word lines, the threshold voltage of the corresponding memory cells are desired to be maintained at an initially set level. However, the threshold voltage of the memory cells may change or decrease depending on various causes. For example, the injected charge may be lost or changed by lateral spreading of the nitride film over time. At this time, the threshold voltage of the memory cells of the special function word line may change, which may seriously damage the reliability of the memory cells in which user data is stored. In order to manage the threshold voltage of the above-described special function word lines(coded GSL, programmable SSL, dummy WL, center dummy WL), in some implementations, it can be managed before the programming of the surrounding main memory cells (hereinafter, cells in which user data is written).

The row decoder 1200 may select the word line of the cell array 1100 in response to the row address R_ADD. The row decoder 1200 provides the word line voltage VWL provided from the voltage generator 1500 to the selection lines SSL and GSL and the word line WL of the memory block selected in the cell array 1100. The row decoder 1200 may select a word line during a program or read operation. The row decoder 1200 may provide a program voltage or a read voltage to the selected word line. These selection lines SSL and GSL and word line WL driving operations are equally applied when accessing special function word lines (coded GSL, programmable SSL, dummy WL, and center dummy WL).

The page buffer circuit 1300 may be connected to the cell array 1100 through bit lines (BL0 to BLj-1, where j is a positive integer). The page buffer circuit 1300 may precharge or sense bit lines (BL0 to BLj-1) connected to the memory cell in response to a page buffer control signal PB_C provided from the control logic circuit 1400. The page buffer circuit 1300 may include a plurality of page buffers (PB0 to PBj-1). A plurality of page buffers PB0 to PBj-1 may be respectively connected to memory cells through a plurality of bit lines BL0 to BLj-1. The page buffer circuit 1300 may operate as a write driver or a sense amplifier depending on the operation mode.

The control logic circuit 1400 may control various operations within the non-volatile memory device 1000 depending on the mode. The control logic circuit 1400 may perform program, read, erase operations for the cell array 1100 in response to a control signal CTRL, a command CMD, and/or an address ADDR. For example, the control logic circuit 1400 may generate a pump enable signal PUMP_En, a page buffer control signal PB_C, etc. for the program operation. The control logic circuit 1400 may control the voltage required for read, write, and erase operations by providing a pump enable signal PUMP_En to the voltage generator 1500.

When a specific word line is selected from a memory block for a program operation, the control logic circuit 1400 may perform a management operation on the special function word lines (coded GSL, programmable SSL, dummy WL, center dummy WL) of the present disclosure. For example, when the word line selected for the program is located at the top from the substrate, the control logic circuit 1400 may perform a threshold voltage management operation on any one of the special function word lines. For example, when a specific word line is selected for the program, the control logic circuit 1400 may perform a threshold voltage check and/or a program on any one of the plurality of coded GSLs. If it is determined that a program is required based on a threshold voltage check (or charge leakage) for memory cells of multiple coded GSLs, the memory cells of the corresponding coded GSLs may be programmed with a predetermined pattern. When the program for the memory cells of the coded GSLs is completed, the memory cells of a specific word line selected for the program will be programmed thereafter. This method may also be applied to other special function word lines (programmable SSL, dummy WL, centered dummy WL).

The voltage generator 1500 may generate a word line voltage VWL required to read or write data in response to a pump enable signal PUMP_En from the control logic circuit 1400. The word line voltage VWL may be provided to a selected word line or an unselected word line through the row decoder 1200. In general, during a read operation, a read voltage will be applied to a selected word line, and a read pass voltage will be applied to an unselected word line. However, the word line voltage VWL is not limited to the voltage applied during a read operation, and may further include voltages according to the operation mode, such as program or erase.

According to the non-volatile memory device 1000, management operations for special function word lines in which user data is not stored may be efficiently performed. Accordingly, a high density non-volatile memory device may be implemented through special function word lines. In addition, high data reliability of the non-volatile memory device 1000 may be maintained without performance degradation through the management operations of special function word lines.

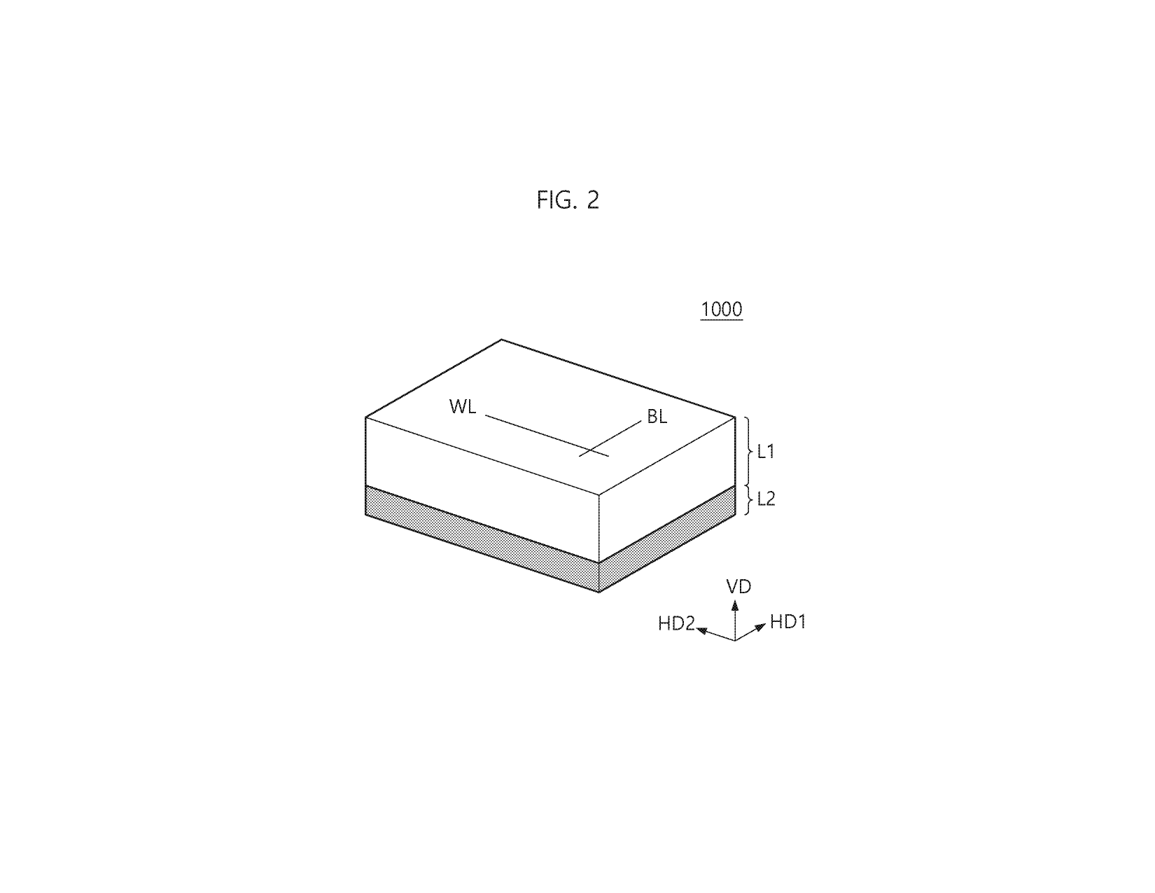

FIG. 2 is a block diagram schematically showing an example of a non-volatile memory device according to some implementations. In FIG. 2, a non-volatile memory device 1000 may include a first semiconductor layer L1 and a second semiconductor layer L2, and the first semiconductor layer L1 may be stacked in a vertical direction VD relative to the second semiconductor layer L2. Specifically, the second semiconductor layer L2 may be arranged below the first semiconductor layer L1 in a vertical direction VD, and thus, the second semiconductor layer L2 may be arranged close to the substrate.

In some implementations, the cell array 1100 of FIG. 1 may be formed on the first semiconductor layer L1, and peripheral circuits corresponding to the row decoder 1200, page buffer circuit 1300, control logic circuit 1400, and voltage generator 1500 of FIG. 1 may be formed on the second semiconductor layer L2. Accordingly, the non-volatile memory device 1000 may have a structure in which the cell array 1100 is arranged on top of the peripheral circuit, i.e., a Cell Over Periphery (COP) structure. The COP structure can effectively reduce the horizontal area and improve the integration of the non-volatile memory device 1000.

In some implementations, the second semiconductor layer L2 may include a substrate, and a peripheral circuit may be formed on the second semiconductor layer L2 by forming transistors and metal patterns for wiring the transistors on the substrate. After the peripheral circuit is formed on the second semiconductor layer L2, the first semiconductor layer L1 including a cell array 1100 may be formed, and metal patterns may be formed to electrically connect the word lines WLs and bit lines BLs of the cell array 1100 and the peripheral circuit formed on the second semiconductor layer L2. For example, the bit lines BLs may extend in the first horizontal direction HD1, and the word lines WLs may extend in the second horizontal direction HD2.

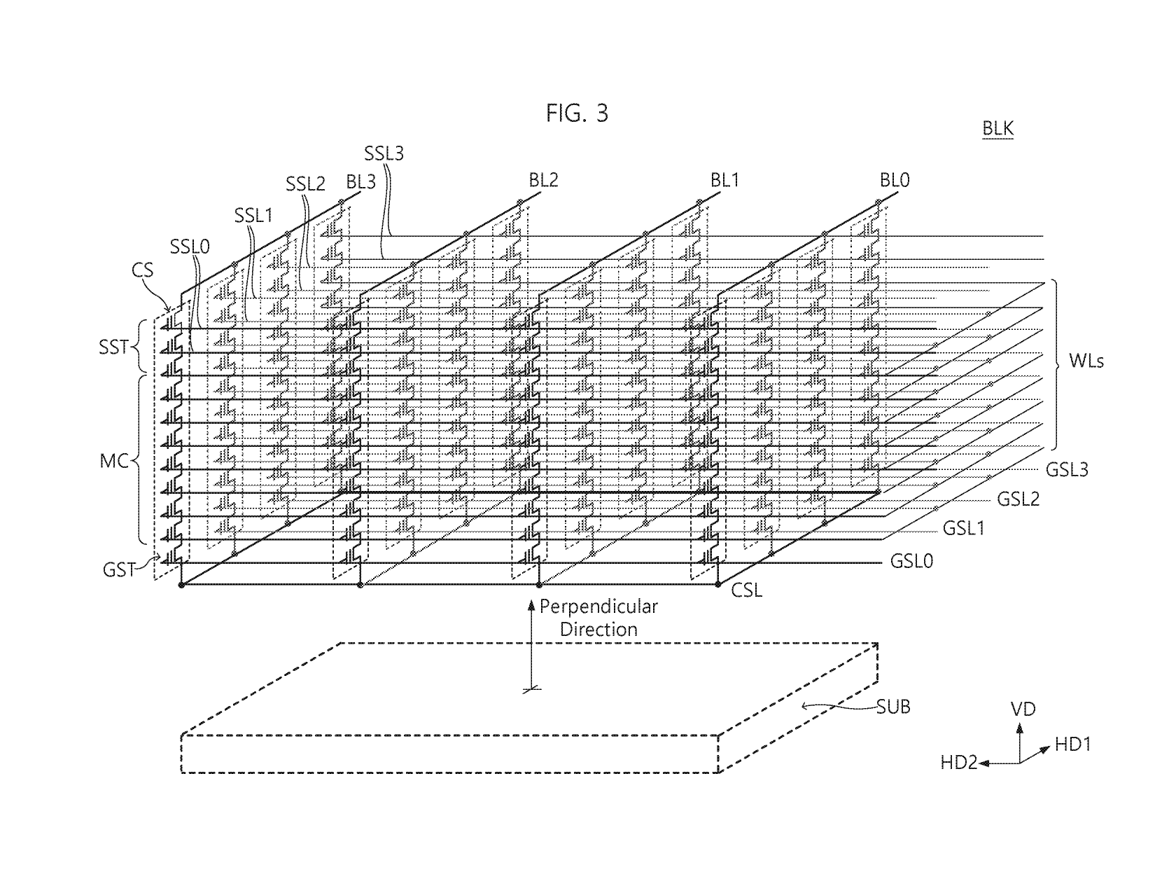

FIG. 3 is a circuit diagram showing an example of a memory block constituting the cell array of FIG. 1 according to some implementations. In FIG. 3, cell strings CS are formed between bit lines BL0, BL1, BL2 and BL3 and a common source line CSL to configure a memory block BLK.

A plurality of cell strings are formed between a bit line BL0 and a common source line CSL. A string selection transistor SST of the cell strings CS is connected to a corresponding bit line BL. A ground selection transistor GST of the cell strings CS is connected to a common source line CSL. Memory cells MCs are provided between the string selection transistor SST and the ground selection transistor GST of the cell strings CS.

Each of the cell strings CS includes the ground selection transistor GST. The ground selection transistors included in the cell strings CS may be controlled by a ground selection line GSL. In some implementations, the cell strings CSs corresponding to each row may be controlled by different ground selection lines GSLs.

The circuit structure of memory cells included in one memory block BLK has been briefly described above. However, the circuit structure of the illustrated memory block is a simplified structure for convenience of explanation, and the actual memory block is not limited to the illustrated example. That is, it will be well understood that one physical block may include more semiconductor layers, bit lines BLs, and string selection lines SSLs.

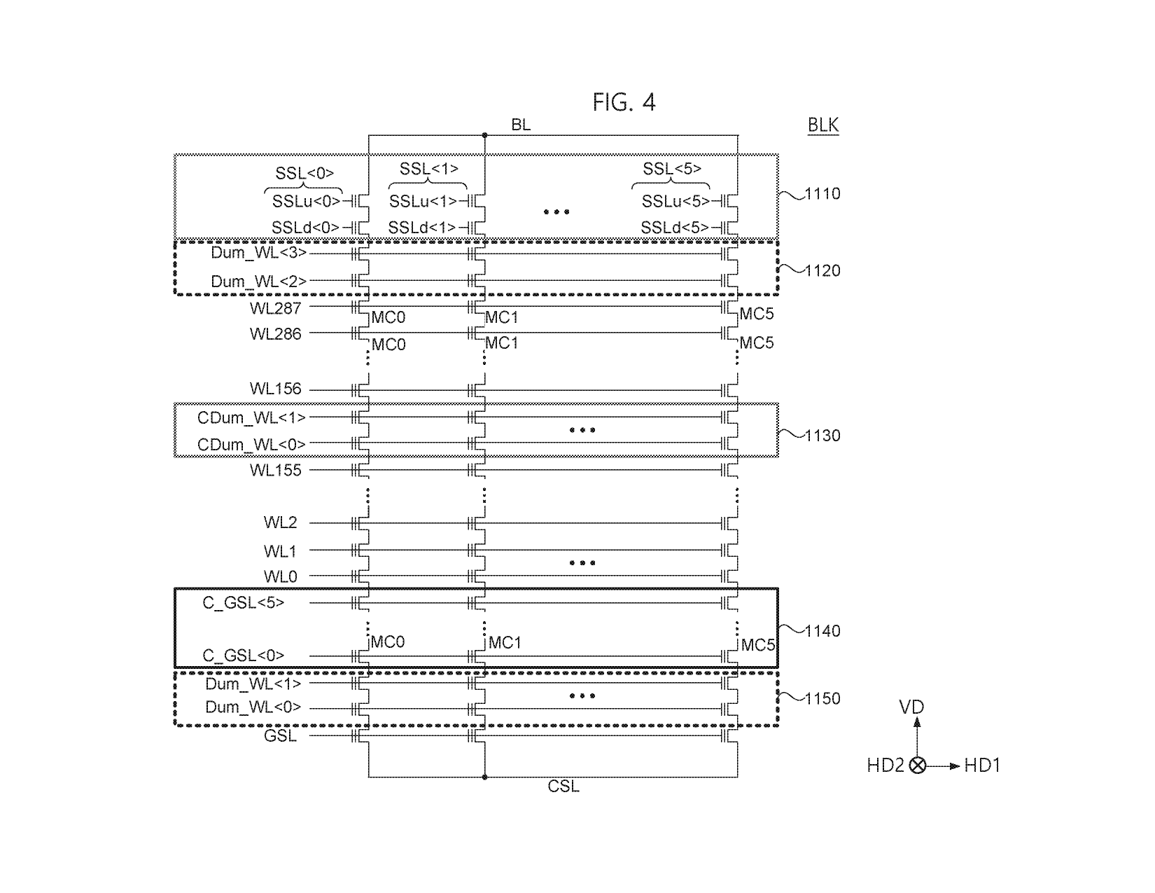

FIG. 4 is a circuit diagram showing examples of special function word lines of the present invention within the memory block of FIG. 3 according to some implementations. In FIG. 4, a memory block BLK may include main word lines WL0~WL287, ground selection lines GSLs, and special function word lines (Programmable SSL, Dum_WL<0>~Dum_WL<3>, CDum_WL<0>, CDum_WL<1>, C_GSL<0>~C_GSL<5>).

Data storage memory cells MCs for storing user data are connected to the main word lines WL0~WL287. In general, among the main word lines WL0~WL287, memory cells of word lines adjacent to selection lines GSL and SSL have relatively poor characteristics. Accordingly, if most of the memory cells connected to the main word lines WL0~WL287 are used as TLC memory cells, the memory cells connected to the word lines adjacent to the selection lines GSL and SSL may be used as MLC or SLC. For example, among the main word lines WL0~WL287, the memory cells connected to the main word lines WL1~WL286 may be used as TLC memory cells. On the other hand, the memory cells connected to the highest main word line WL287 and the lowest main word line WL0 may be managed as MLC.

Generally, the memory cells of the highest main word line WL287 in the memory block BLK may be programmed first. Or, the lowest main word line WL0 may be programmed first. In the present invention, it is assumed that the word line selected for programming first in the memory block BLK is the highest main word line WL287. And the word line that is selected first during program operation is called a 'specific word line'. It will be well understood that in another embodiment, the specific word line may be the lowest main word line WL0.

The special function word lines may include a programmable SSL 1110, dummy word lines Dum_WL<0>~Dum_WL<3>, center dummy word lines (CDum_WL<0>~CDum_WL<1>, 1130), and coded GSLs (C_GSL<0>~C_GSL<5>, 1140).

The programmable SSL 1110 is connected to gates of the string selection transistors SSTs to select a cell string in the memory block BLK. In FIG. 4, programmable SSL 1110 may be extended in the vertical direction HD2 of the ground. A turn-on voltage can be provided to a string selection transistor SST connected to a selected cell string, and a turn-off voltage can be provided to a string selection transistor SST connected to an unselected cell string. In order to maintain the reliability of this selection operation, the threshold voltage level of the string selection transistors SSTs connected to the programmable SSL 1110 may be checked before the memory cells of a specific word line (e.g., WL287) are programmed. And, according to the threshold voltage check result of the string selection transistors SSTs, the memory cells of a specific word line (e.g., WL287) may be programmed.

The programmable SSL 1110 may include upper string selection lines SSLu<0> to SSLu<5> and lower string selection lines SSLd<0> to SSLd<5>. The upper string selection lines SSLu<0> to SSLu<5> and lower string selection lines SSLd<0> to SSLd<5> may be configured to be connected to different pocket wells during an erase operation. However, during a program operation, the same level will be provided to the upper string selection lines SSLu<0> to SSLu<5> and lower string selection lines (SSLd<0> to SSLd<5>).

Dummy word lines Dum_WL<0> to Dum_WL<3>(1120, 1150) may be provided to prevent hot electron injection HCI degradation due to negative boosting in a channel of a selected cell string. For example, when a read recovery operation is performed when a read operation is interrupted, a predetermined level (e.g., a recovery level) is provided to the main word lines WL0 to WL287. During the read recovery operation, as the voltage level of the main word lines WL0 to WL287 decreases, hot electron injection HCI may occur due to a drop in the channel voltage caused by negative boosting occurring in the channel of the cell string. In this case, memory cells in an erased state among the memory cells connected to the main word lines WL0 to WL287 may be programmed, which may deteriorate reliability. Accordingly, by floating the dummy word lines Dum_WL<0>~Dum_WL<3> during read recovery operation, the negative boosting phenomenon of the channel can be blocked and the hot electron injection HCI degradation may be prevented. In order to ensure high reliability of the dummy word lines Dum_WL<0>~Dum_WL<3>, a program for the dummy cells connected to the dummy word lines Dum_WL<0>~Dum_WL<3> is required when necessary.

The center dummy word line 1130 is formed in the center part of the main word lines WL0~WL287. The center dummy word line 1130 is managed for channel local boosting in stack units. And it can also be used for the purpose of increasing boosting efficiency. In the end, the center dummy word line 1130 only needs to be checked or programmed for threshold voltage before the memory cells connected to the main word lines WL0 to WL155 of the lower stack are programmed. Accordingly, the threshold voltage check or program of the center dummy word line 1130 needs to be performed before a specific word line (e.g., WL155) is programmed. And the threshold voltage check and program of the center dummy word line 1130 may be performed when a specific word line (e.g., WL155) of the lower stack is selected.

The coded GSLs (C_GSL<0> to C_GSL<5>. 1140) may be used to reduce the channel capacity of the unselected string selection line SSL when the memory cells of the main word lines WL0 to WL287 are programmed. For example, when a program command is provided for memory cell MC0 of a specific word line (e.g., WL287), only memory cells of the coded GSL C_GSL<0> may be programmed to the erase state ‘E’ or the program state ‘P’. That is, the memory cell MC0 of the coded GSL C_GSL<0> can be programmed to the erase state ‘E’, and the remaining memory cells MC1 to MC5 of the coded GSL C_GSL<0> can be programmed to the program state ‘P’. Then, when the pass voltage or word line voltage is provided to the main word lines WL0~WL287 or the coded GSLs C_GSL<0>~C_GSL<5> during program operation, only the channels of the cell strings connected to the string selection line SSL<0> will be activated, and the channels of the cell strings connected to the remaining string selection lines (SSL<1>~SSL<5>) will be floated. The setting method of the coded GSLs C_GSL<0>~C_GSL<5> will be described in more detail through the drawings described below.

The special function word lines 1110, 1120, 1130, 1140, and 1150 have been briefly described above. In particular, for memory cells connected to special function word lines 1110, 1120, 1130, 1140, and 1150, threshold voltages may be checked and/or programmed before programming memory cells of a specific word line.

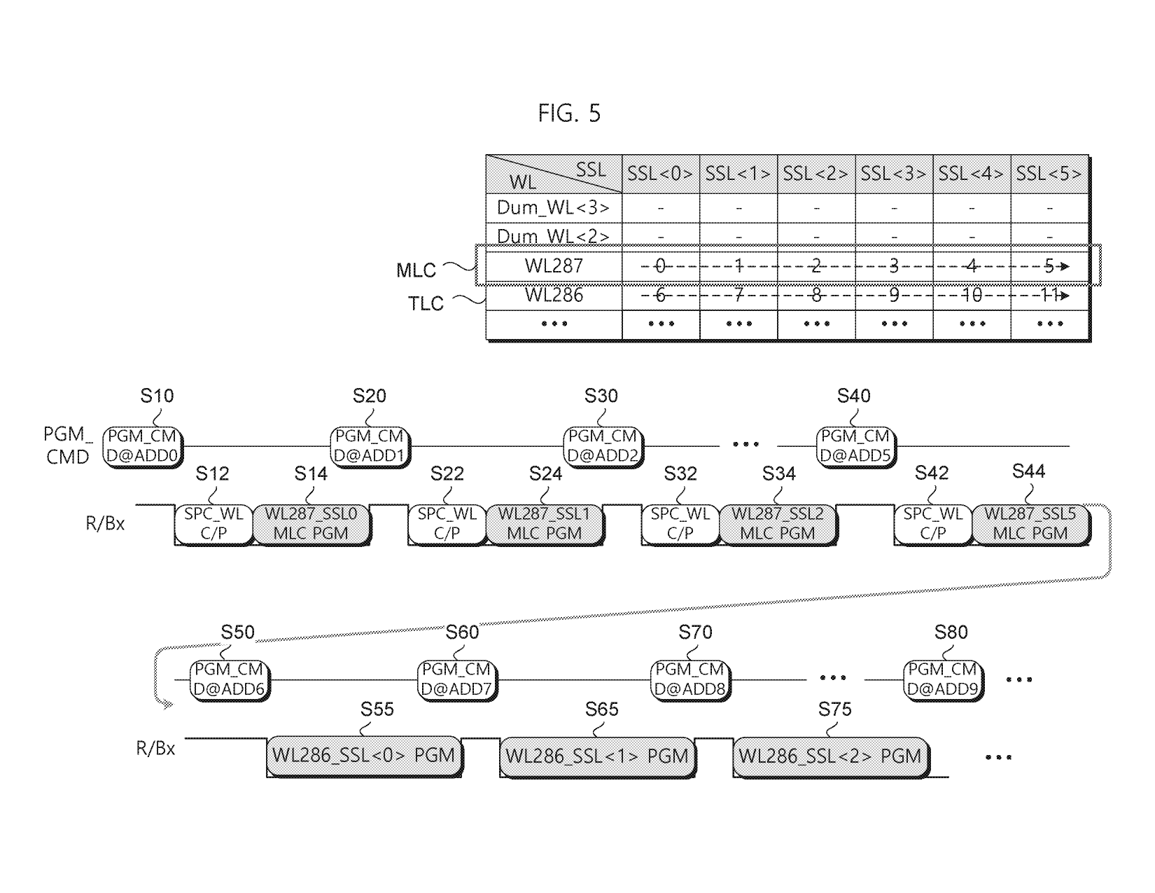

FIG. 5 is a diagram showing examples of a command sequence and a program sequence according to the some implementations. In FIG. 4 and FIG. 5, assume that the memory block BLK includes six string selection lines SSL0 to SSL5, main word lines WL0 to WL287 and special function word lines (SSL, Dum_WL<0> to Dum_WL<3>, CDum_WL<0>, CDum_WL<1>, C_GSL<0> to C_GSL<5>).

It is assumed that the program order of the main word lines WL0 to WL287 starts from the highest main word line WL287. In addition, the selected highest main word line WL287 may be sequentially selected from the string selection line SSL<0> to the string selection line (SSL<5>). Here, it is assumed that the highest main word line WL287 is managed as a multi-level cell (MLC), and the remaining main word lines (WL0~WL286) are managed as a triple-level cell (TLC).

The program command may be expressed in the form of 'PGM_CMD@ADD0'. At this time, selection information of the word line and string selection line SSL is provided through the address 'ADDn'. When the program command 'PGM_CMD@ADD0' is provided, the highest main word line WL287 is selected. Then, the string selection lines SSL<0>, SSL<1>, SSL<2>, SSL<3>, SSL<4> and SSL<5> of the highest main word line WL287 are sequentially selected to select the cell string. In particular, in some implementations, when the highest main word line WL287 corresponding to a specific word line is selected, the non-volatile memory device (1000, see FIG. 1) performs a threshold voltage check and/or a program operation for memory cells connected to the special function word line.

In step S10, a program command 'PGM_CMD@ADD0' is provided. Then, the control logic circuit (1400, see FIG. 1) will recognize the program command for the memory cells connected to the string selection line SSL<0> among the memory cells of the highest main word line WL287. And in step S12, the control logic circuit 1400 performs a threshold voltage check and/or a program operation (SPC_WL C/P) for the memory cells connected to the special function word line. The special function word line may be at least one of the programmable SSL 1110, dummy word lines Dum_WL<0> to Dum_WL<3>(1120, 1150), center dummy word lines (CDum_WL<0> to CDum_WL<1>, 1130), and coded GSLs (C_GSL<0> to C_GSL<5>, 1140). Subsequently, in step S14, the control logic circuit 1400 performs a program operation on the memory cells connected to the string selection line SSL<0> of the highest main word line WL287. In this manner, before the program of the memory cells connected to the string selection line SSL<0> of the highest main word line WL287, a threshold voltage check and/or a program is performed on the memory cells of the special function word lines.

In step S20, a program command 'PGM_CMD@ADD1' is provided. Then, the control logic circuit 1400 will identify the program command for the memory cells connected to the string selection line SSL<1> among the memory cells of the highest main word line WL287. Accordingly, in step S22, the control logic circuit 1400 performs the threshold voltage check and/or program operation (SPC_WL C/P) for the memory cells connected to the special function word line. Then, in step S24, the control logic circuit 1400 performs a multi-level cell MLC program for the memory cells connected to the string selection line SSL<1> of the highest main word line WL287. In the same manner, the check and/or program for the memory cells of the special function word lines is performed at steps S32 and S42 according to the program commands provided at steps S30 and S40.

The program of the memory cells of the highest main word line WL287 will be terminated in step S44, and the program command 'PGM_CMD@ADD6' for the memory cells of the main word line WL286 will be provided in step S50. Then, in step S55, the control logic circuit 1400 will perform a triple-level cell TLC program operation for the memory cells connected to the string selection line SSL<0> of the main word line WL286 without checking the threshold voltage for the memory cells. Thereafter, in step S60, the program command 'PGM_CMD@ADD7' for the memory cells of the main word line WL286 will be provided. Then, in step S65, the control logic circuit 1400 will perform a triple-level cell TLC program operation for the memory cells connected to the string selection line SSL<1> of the main word line WL286. For the program commands provided in the S70 and S80 steps, the control logic circuit 1400 will perform a triple-level cell TLC program operation for the memory cells connected to the string selection lines (SSL<2>, SSL<3>, …) of the main word line WL286 without the threshold voltage check operation.

According to some implementations, when a program command for a specific word line (e.g., WL287) is provided, the threshold voltage check and/or the program operation for the memory cells connected to the corresponding special function word lines are first performed. After that, the program operation of the memory cells connected to the specific word line (e.g., WL287) may be performed. By applying the management method of the memory cells connected to these special function word lines, high data reliability may be provided without performance degradation.

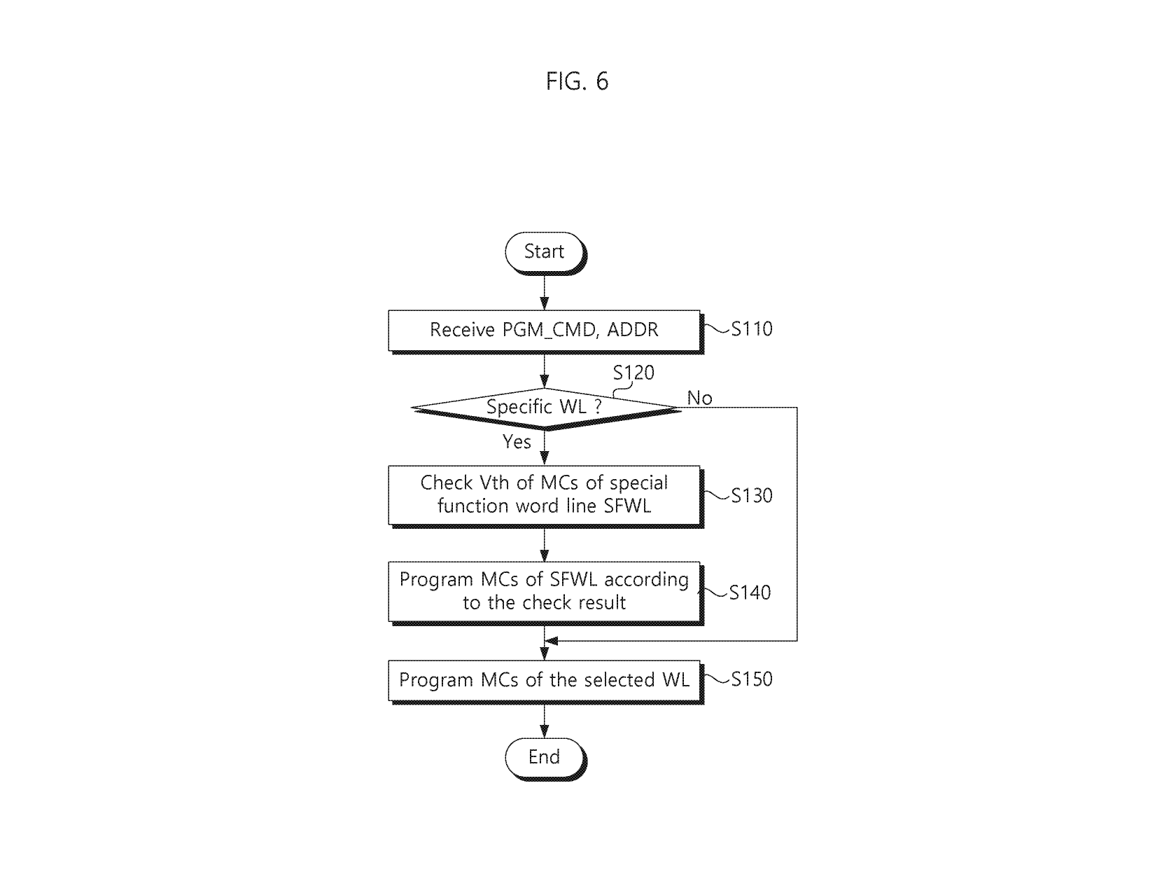

FIG. 6 is a flowchart showing an example of a management method of the memory cells connected to special function word lines according to some implementations. In FIG. 6, a threshold voltage check and/or a program operation are performed on memory cells of special function word lines of the present invention in response to a program command in which a specific word line (e.g., WL287) is selected.

In step S110, the non-volatile memory device 1000 receives a program command PGM_CMD and an address ADDR.

In step S120, the control logic circuit 1400 determines whether the selected word line corresponds to a specific word line (e.g., WL287) through the address ADDR. If the selected word line is the specific word line, the procedure moves to step S130. On the other hand, if the selected word line is not the specific word line, the procedure skips to step S150.

In step S130, the control logic circuit 1400 performs a threshold voltage check operation on memory cells MCs connected to the special function word line. Here, the special function word line may be at least one of the programmable SSL 1110, dummy word lines Dum_WL<0>~Dum_WL<3>, center dummy word lines CDum_WL<0>~CDum_WL<1>, and coded GSLs C_GSL<0>~C_GSL<5>. The threshold voltage check operation for the memory cells MCs connected to the special function word line may be performed by counting the number of memory cells having a threshold voltage lower than a specific voltage. If the number of memory cells having the threshold voltage lower than the specific voltage is equal to or greater than a reference value, a program for the memory cells MCs connected to the special function word line is required.

In step S140, the control logic circuit 1400 performs a program operation on memory cells MCs connected to the special function word line according to the result of the threshold voltage check operation. If the number of memory cells having the threshold voltage lower than a specific voltage is greater than or equal to a reference value, the control logic circuit 1400 will perform a program operation on the memory cells MCs connected to the special function word line. On the other hand, if the number of memory cells having the threshold voltage lower than a specific voltage is less than or equal to a reference value, the control logic circuit 1400 may skip the program operation on the memory cells MCs connected to the special function word line.

In step S150, when the program operation on the memory cells MCs connected to the special function word line is completed, the memory cells of the word line selected through the address ADDR will be programmed.

In the above, when a program command for a specific word line (e.g., WL287) is received, a procedure for performing the threshold voltage check and/or program operation on memory cells MCs connected to the special function word line has been described. Through management of memory cells MCs connected to the special function word line, the non-volatile memory device 1000 may provide high data reliability.

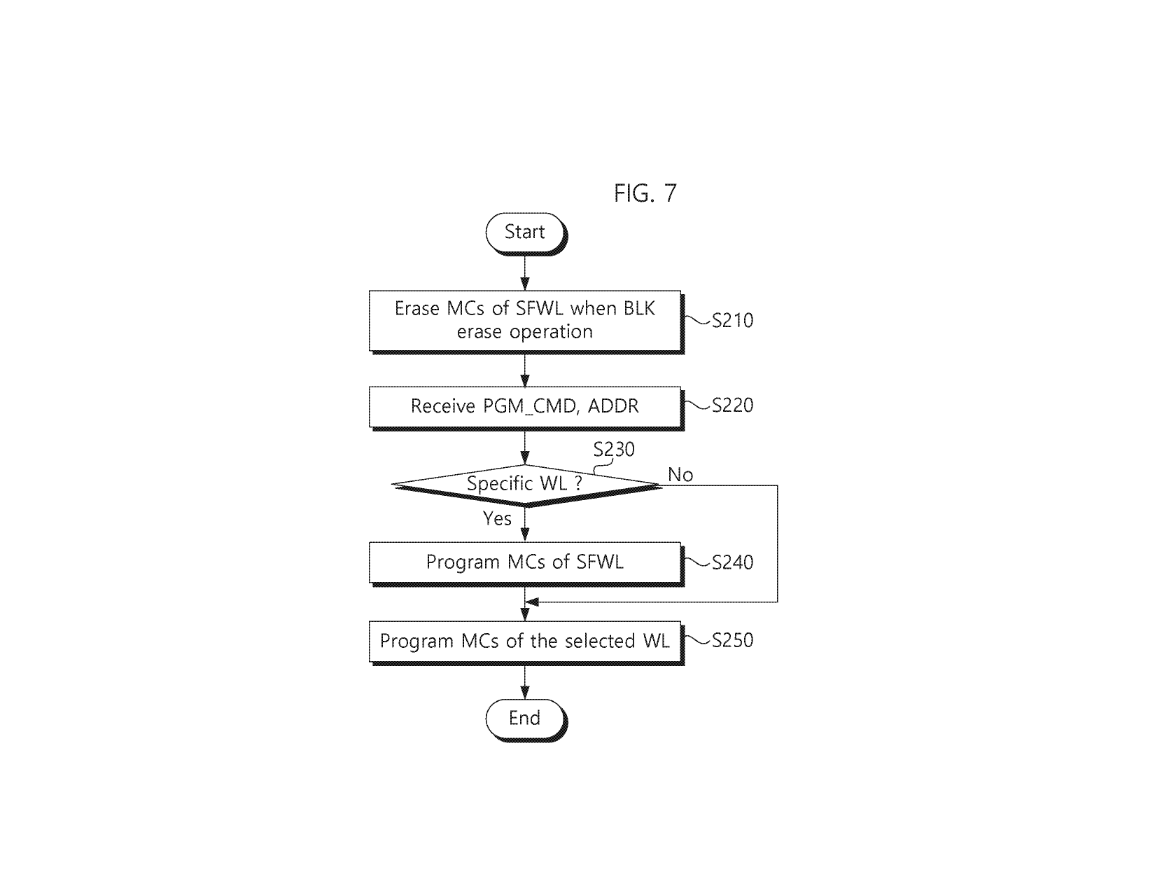

FIG. 7 is a flowchart showing an example of a method of managing memory cells connected to special function word lines according to some implementations. In FIG. 7, memory cells of special function word lines SFWL are erased during a block erase operation. Then, a program for memory cells of special function word lines SFWL may be performed in response to a program command in which a specific word line (e.g., WL287) is selected.

In step S210, memory cells of special function word lines SFWL are erased during a block erase operation. Accordingly, memory cells of special function word lines SFWL may be maintained in an erased state.

In step S220, the non-volatile memory device 1000 receives a program command PGM_CMD and an address ADDR.

In step S230, the control logic circuit 1400 determines whether the selected word line correspond to a specific word line (e.g., WL287) through the address ADDR. If the selected word line corresponds to the specific word line, the procedure moves to step S240. On the other hand, if the selected word line is not the specific word line, the procedure skips to step S250.

In step S240, the control logic circuit 1400 performs a program operation for the memory cells MCs connected to the special function word line. Here, the special function word line may be at least one of the programmable SSL 1110, dummy word lines Dum_WL<0>~Dum_WL<3>, center dummy word lines CDum_WL<0>~CDum_WL<1>, and coded GSLs C_GSL<0>~C_GSL<5>.

In step S250, memory cells of the main word line selected through the address ADDR are programmed in a state where the program for the memory cells MCs connected to the special function word line is completed.

In the above, when a program command for a specific word line (e.g., WL287) is received, the execution procedure of the program operation for the memory cells MCs connected to the special function word line has been described. The memory cells MCs connected to the special function word line are erased during the block erase operation. Accordingly, before a specific word line (e.g., WL287) is programmed, memory cells MCs connected to the special function word line are forcibly programmed without a threshold voltage check operation.

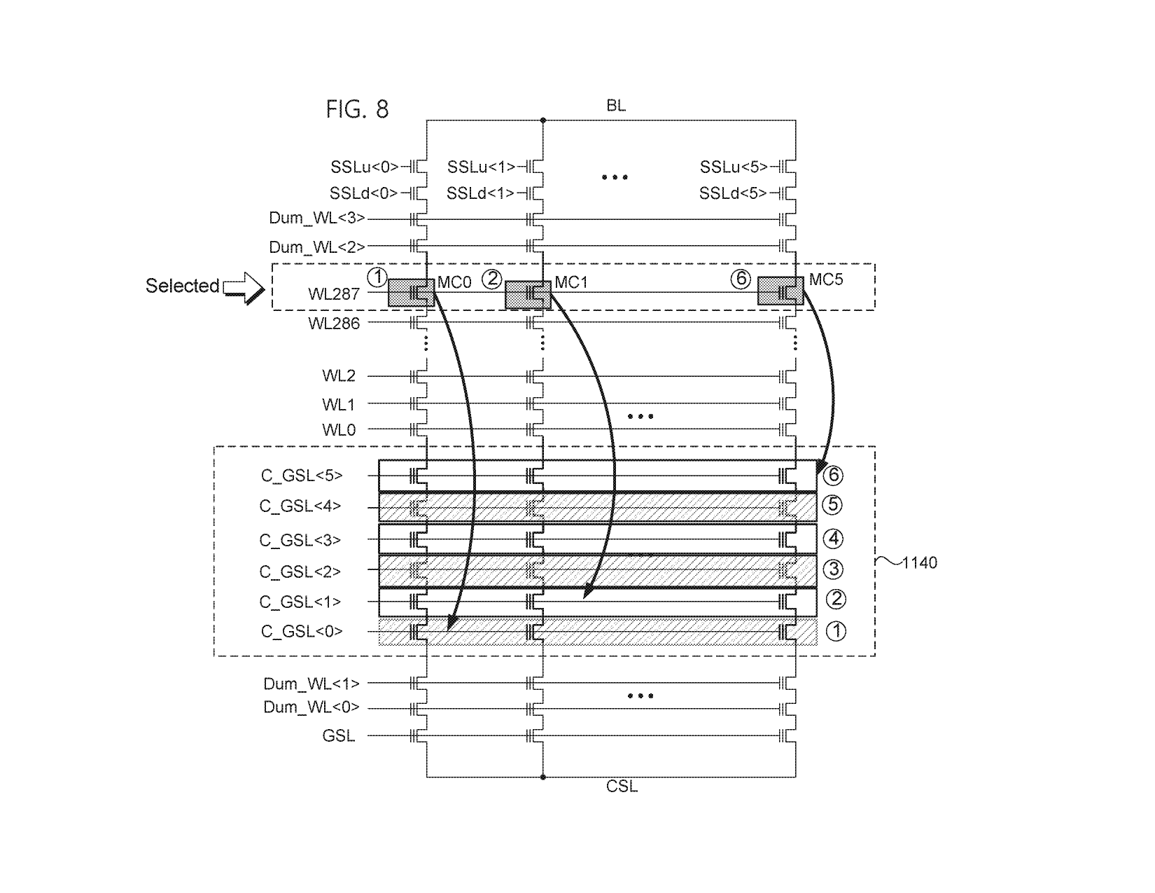

FIG. 8 is a diagram showing an example of a programming method of a coded GSL that includes a type of a special function word line SFWL according to some implementations. In FIG. 8, the coded GSL 1140 may be formed of layers corresponding to the number of string selection lines. Then, when a specific word line (e.g., WL287) and a string selection line (SSL<i>, an integer of 0≤i≤5) are selected for programming, memory cells connected to the coded GSL C_GSL<i> of the corresponding layer may be programmed.

The situation in which a specific word line (e.g., WL287) and a string selection line SSL<0> are selected for programming is referred to as '① Situation'. Then, in '① situation', the control logic circuit (1400, see FIG. 1) performs a threshold voltage check and/or a program operation on the memory cells connected to the coded GSL C_GSL<0> before performing a program operation on the main memory cells connected to the specific word line WL287 and the string selection line SSL<0>. In other words, in '① situation', the threshold voltage status of the memory cells connected to the coded GSL C_GSL<0> may be checked. If it is determined that the threshold voltage status of the memory cells connected to the coded GSL C_GSL<0> requires a program, the program operation on these memory cells may be performed in cell string units. For example, among the memory cells connected to the coded GSL C_GSL<0>, the memory cells corresponding to the string selection line SSL<0> will be programmed to an erase state ‘E’. And among the memory cells connected to the coded GSL C_GSL<0>, the memory cells corresponding to the string selection lines SSL1 to SSL5 will be programmed to a program state ‘P’ higher than the erase state ‘E’.

The situation in which a specific word line WL287 and the string selection line SSL<1> are selected for the program will be referred to as the '② situation'. Then, in the '② situation', the control logic circuit 1400 performs a threshold voltage check and/or a program operation on the memory cells connected to the coded GSL C_GSL<1> before performing a program operation on the main memory cells connected to the specific word line WL287 and the string selection line SSL<1>. That is, in the '② situation', the threshold voltage state of the memory cells connected to the coded GSL C_GSL<1> may be checked. If the threshold voltage status of the memory cells connected to the coded GSL C_GSL<1> is determined to require a program, the program operation on these memory cells may be performed in cell string units. For example, among the memory cells connected to the coded GSL C_GSL<1>, the memory cells corresponding to the string selection line SSL<1> will be programmed to an erase state ‘E’. And among the memory cells connected to the coded GSL C_GSL<1>, the memory cells corresponding to the string selection lines SSL<0>, SSL<2> to SSL<5> will be programmed to the program state ‘P’ higher than the erase state ‘E’.

In the '③ situation', '④ situation', '⑤ situation', and '⑥ situation' where a specific word line and string selection line SSL<i> is selected, threshold voltage check and/or program operation are performed on the memory cells of the coded GSL C_GSL<i> just like in the '① situation' or '② situation'. The pattern programmed on the memory cells of the coded GSL C_GSL<i> will be described through the table described below.

As described above, when a specific word line and string selection line SSL<i> is selected for a program operation, the memory cells of the coded GSL C_GSL<i> of the corresponding layer may be checked and/or programmed. And after the programming of the memory cells of the corresponding coded GSL C_GSL<i>, the program operation on the main memory cell connected to the specific word line will be performed. Accordingly, the time required to check and/or program operation on the memory cells of the coded GSL C_GSL<i> does not significantly affect the total program time tPROG. On the other hand, the reliability of the coded GSL C_GSL<i> may be improved.

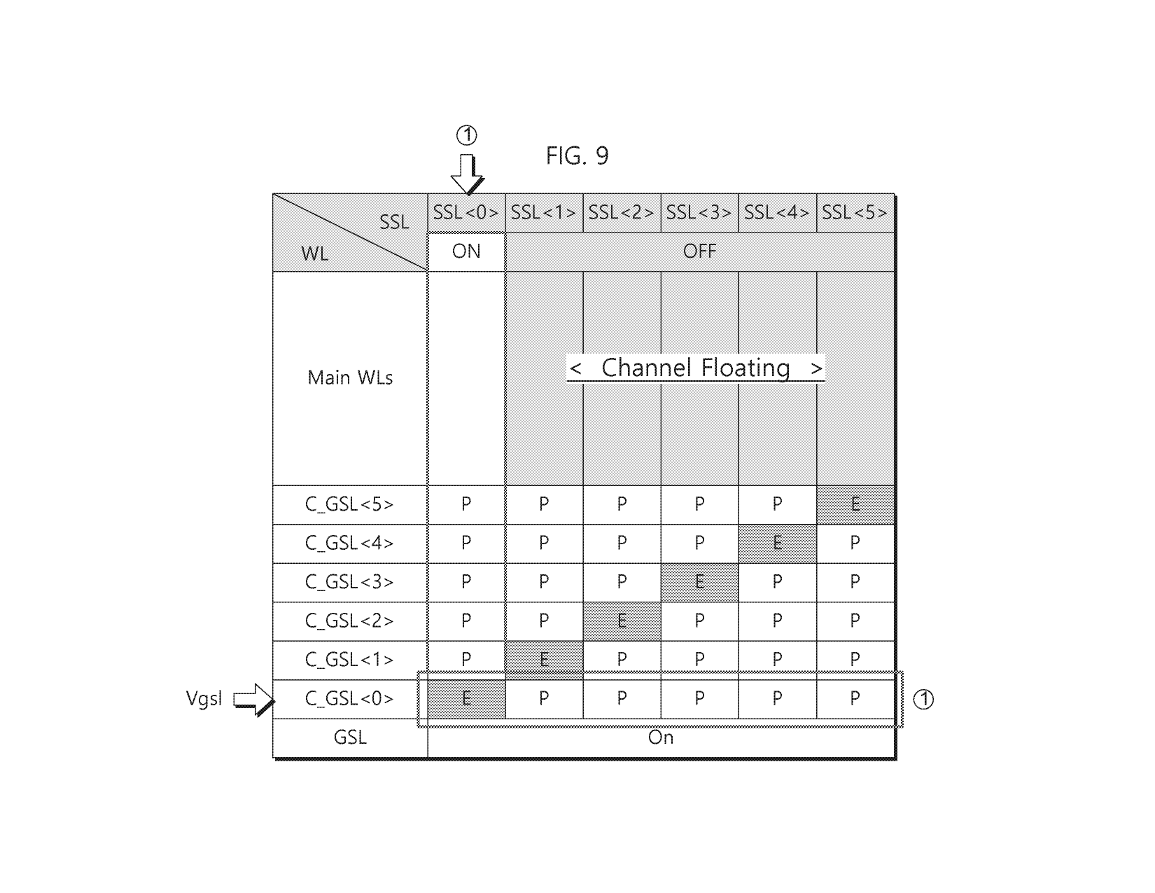

FIG. 9 is a table showing an example of a pattern code programmed into memory cells of a coded GSL according to some implementations. In FIG. 9, when a specific word line (WL287, not shown) and a string selection line SSL<0> are selected for a program operation, only the memory cells of a corresponding coded GSL C_GSL<0> may be programmed.

First, in '① situation', it is assumed that the coded GSL C_GSL<0> is programmed with a pattern code (E, P, P, P, P, P). Then, the string selection line SSL<0> and the ground selection line GSL will be activated (or, On) for programming the memory cells of the selected main word line. And the unselected string selection lines SSL<1> to SSL<5> are deactivated, and a program voltage Vpgm or a pass voltage Vpass is provided to the main word lines for programming the memory cells of the main word lines. In addition, a control voltage (Vgsl, for example, 0V) may be provided to the coded GSL C_GSL<0>. Then, the channel of the cell string selected by the selected string selection line SSL<0> is connected to the ground. On the other hand, the channel of the unselected string selection lines SSL<1> to SSL<5> is maintained in an off state by the pattern code (P, P, P, P, P) even though the ground selection line GSL is activated. Accordingly, when the program voltage Vpgm or the pass voltage Vpass is applied to the main word lines, the channels of the non-selected string selection lines SSL<1> to SSL<5> may be maintained in a floating state. As a result, the word line loading may be reduced by the floating of the channels of the non-selected string selection lines SSL<1> to SSL<5>.

If a specific word line WL287 and string selection line SSL<1> are selected for the program, the pattern code (P, E, P, P, P, P) will be programmed into the memory cells of the corresponding coded GSL C_GSL<1>. And, if a specific word line WL287 and string selection line SSL2 are selected for the program operation, the pattern code (P, P, E, P, P, P) will be programmed into the memory cells of the corresponding coded GSL C_GSL<2>. In this way, when a specific word line WL287 and the string selection line SSL<5> are selected for a program, a pattern code (P, P, P, P, P, E) will be programmed into the memory cells of the corresponding coded GSL C_GSL<5>. Through the pattern code program of each coded GSL C_GSL<i>, channel floating of the unselected string selection lines may be guaranteed during the program operation of the main word line.

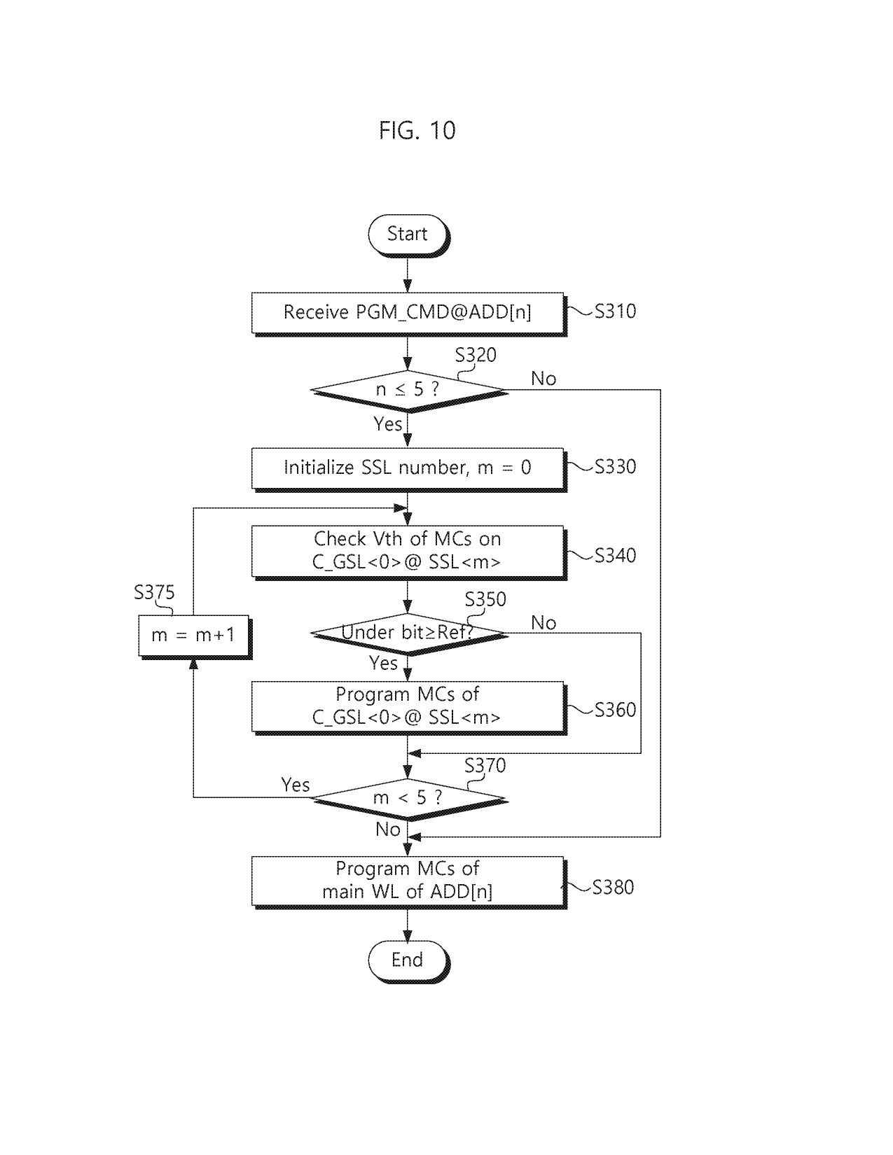

FIG. 10 is a flowchart showing an example of a coded GSL management method according to some implementations. In FIG. 10, a threshold voltage check and/or program operation may be performed on the memory cells connected to the coded GSL C_GSL<i> in response to a program command in which a specific word line (e.g., WL287) is selected.

In step S310, the non-volatile memory device 1000 receives the program command PGM_CMD and an address ADD[n].

In step S320, the control logic circuit 1400 determines whether the selected word line is a specific word line (e.g., the highest word line WL287) through the address ADD[n]. In the case of the highest word line, 'n' included in the address will correspond to '0' or more and '5' or less. If the selected word line is a specific word line (or, the highest word line) ('Yes' direction), the procedure moves to step S330. On the other hand, if the selected word line is not a specific word line ('No' direction), the procedure skips to step S380.

In step S330, the control logic circuit 1400 initializes the selection number 'm' of the string selection line SSL to '0'. In other words, the selection number of the string selection line SSL for sequentially selecting the string selection lines SSL<0> to SSL<5> within the selected coded GSL C_GSL<i> is set to the initial value '0'.

In step S340, the control logic circuit 1400 is connected to the coded GSL C_GSL<0> and performs a threshold voltage check operation for the memory cells MCs selected by the string selection line SSL<0>. The threshold voltage check operation for the memory cells MCs connected to the coded GSL C_GSL<0> may be performed by counting the number of memory cells (hereinafter, under bits) having a threshold voltage lower than a reference level through reading the memory cells MCs connected to the coded GSL C_GSL<0>.

In step S350, the control logic circuit 1400 performs an operation branch according to the result of checking the threshold voltage of the memory cells MCs connected to the coded GSL C_GSL<0>. If the under bit corresponding to the number of memory cells with large charge leakage is greater than or equal to the reference value Ref ('Yes' direction), the procedure moves to step S360. On the other hand, if the under bit is less than the reference value Ref ('No' direction), the procedure moves to step S370.

In step S360, the control logic circuit 1400 will program a pattern code corresponding to the erase state ‘E’ in the memory cells MCs connected to the coded GSL C_GSL<0> controlled by the string selection line SSL<0>.

In step S370, the control logic circuit 1400 checks whether the selection number 'm' of the string selection line SSL has reached the final number '5'. If the selection number 'm' of the string selection line SSL is less than the final number '5' ('Yes' direction), the procedure moves to step S375. On the other hand, if the selection number 'm' of the string selection line SSL is greater than the final number '5' ('No' direction), the procedure moves to step S380.

In step S375, the control logic circuit 1400 increases the selection number 'm' of the string selection line SSL. After that, the procedure returns to step S340 to perform the threshold voltage check operation on the memory cells MCs connected to the coded GSL C_GSL<0> and selected by the string selection line SSL<1>. The memory cells connected to the coded GSL C_GSL<0> may be sequentially programmed with pattern code (E, P, P, P, P, P) through the operation loops composed of steps S340, S250, S360, S370, and S375.

In step S380, after the memory cells of the coded GSL C_GSL<0> are programmed, the memory cells of the selected main word line (e.g., the highest word line WL287) will be programmed.

The above describes the threshold voltage check and the pattern code programming procedure for the memory cells of the coded GSL C_GSL<0>. The channel floating of the unselected cell strings that occurs when the main word line is programmed may be guaranteed by the pattern code programmed in the memory cells of the coded GSL C_GSL<0>. Accordingly, the word line loading caused during the program operation may be significantly reduced.

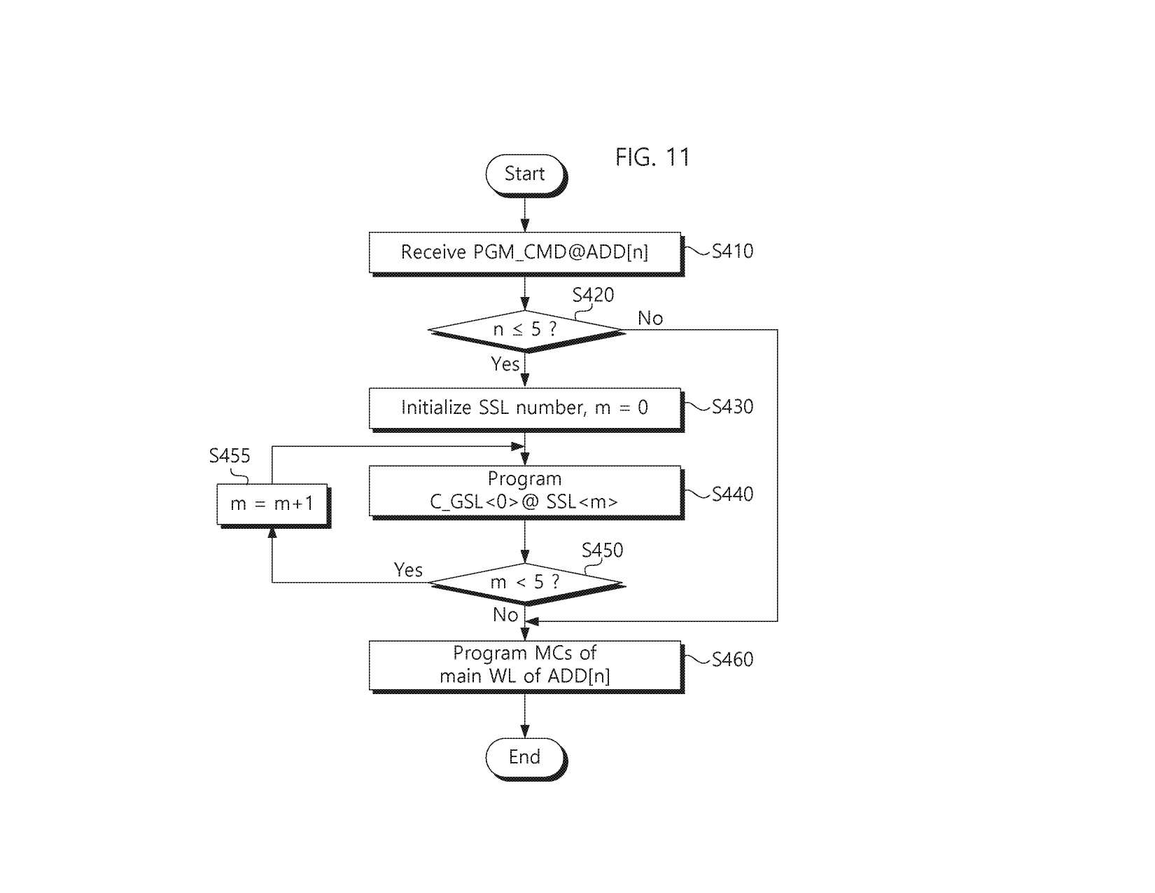

FIG. 11 is a flowchart showing an example of a coded GSL management method according to some implementations. In FIG. 11, a program may be performed on memory cells connected to a coded GSL C_GSL<i> in response to a program command in which a specific word line (e.g., WL287) is selected. In particular, the memory cells of the coded GSL C_GSL<i> are provided in an erased state by a block erase operation. Accordingly, only the program operation on the memory cells connected to the coded GSL C_GSL<i> will be performed in response to a program command in which a specific word line (e.g., WL287) is selected.

In step S410, the non-volatile memory device 1000 receives a program command PGM_CMD and an address ADD[n].

In step S420, the control logic circuit 1400 determines whether the selected word line is a specific word line (e.g., the highest word line WL287) through the address ADD[n]. In the case of the highest word line, 'n' included in the address will correspond to '0' or more and '5' or less. If the selected word line is the specific word line ('Yes' direction), the procedure moves to step S430. On the other hand, if the selected word line is not the specific word line ('No' direction), the procedure skips to step S460.

In step S430, the control logic circuit 1400 initializes the selection number 'm' of the string selection line SSL to '0'.

In step S440, the control logic circuit 1400 will program a pattern code corresponding to the erase state ‘E’ to the memory cells MCs controlled by the string selection line SSL<0> among the memory cells connected to the coded GSL C_GSL<0>.

In step S450, the control logic circuit 1400 checks whether the selection number 'm' of the string selection line SSL has reached the final number '5'. If the selection number 'm' of the string selection line SSL is less than the final number '5' ('Yes' direction), the procedure moves to step S455. On the other hand, if the selection number 'm' of the string selection line SSL is greater than or equal to the final number '5' ('No' direction), the procedure moves to step S460.

In step S455, the control logic circuit 1400 increases the selection number 'm' of the string selection line SSL. Afterwards, the procedure will return to step S440. And the memory cells MCs connected to the coded GSL C_GSL<0> controlled by the string selection line SSL<1> will be programmed with a pattern code corresponding to the erase state ‘E’. The pattern code (E, P, P, P, P, P) may be sequentially programmed to the memory cells connected to the coded GSL C_GSL<0> through the operation loop configured by steps S440, S450, and S455.

In step S460, the program will be performed on the memory cells of the selected main word line (e.g., the highest word line WL287) after the program operation on the memory cells of the coded GSL C_GSL<0> is completed.

The above procedure for programming the pattern code to the memory cells of the coded GSL C_GSL<0> has been described. The channel floating of unselected cell strings that occur when programming the main word line may be ensured by the pattern code programmed in the memory cells of the coded GSL C_GSL<0>.

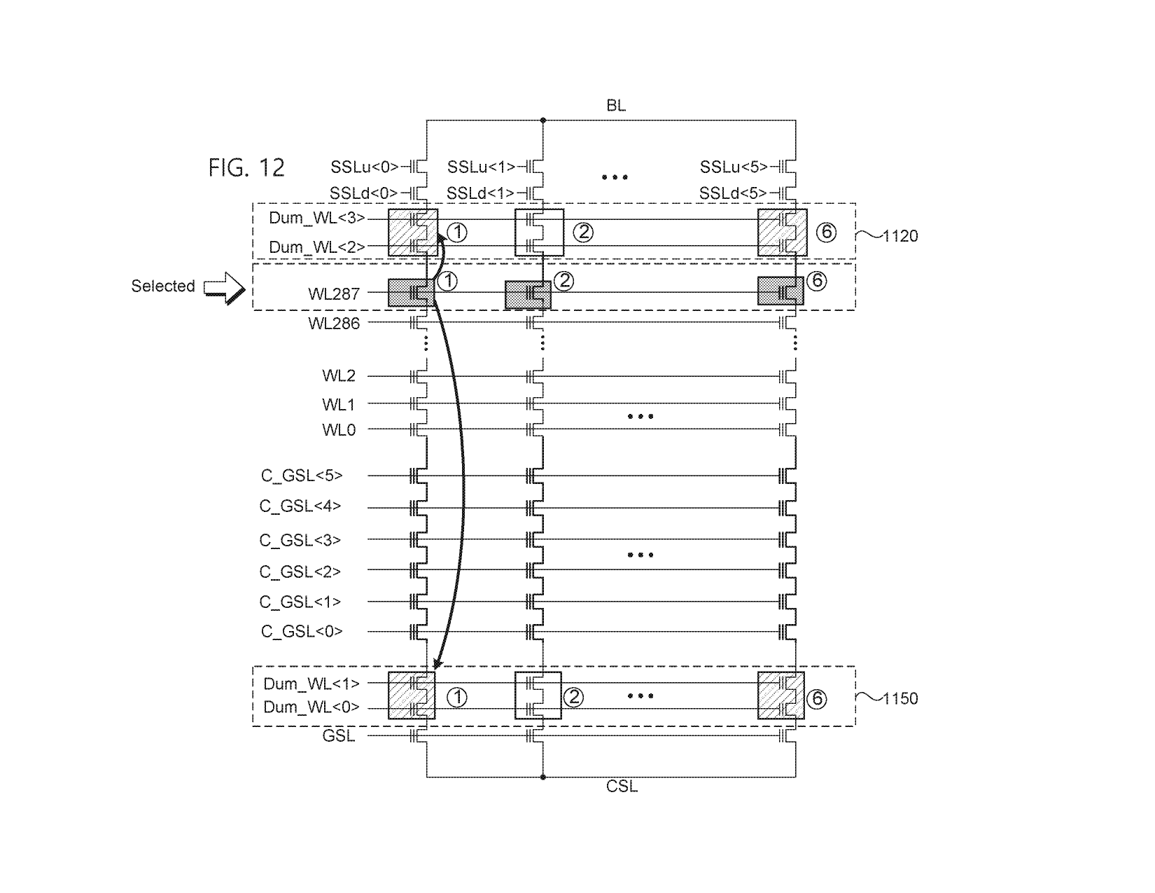

FIG. 12 is a drawing briefly showing a programming method of dummy word lines, which are a type of special function word line SFWL. Referring to FIG. 12, one or more dummy word lines (1120, 1150) may be formed at positions adjacent to the string selection line SSL and the ground selection line GSL, respectively. Then, when a specific word line (e.g., WL287) and a string selection line (SSL<i>, an integer of 0≤i≤5) are selected for programming, a corresponding dummy word line Dum_WL<j> may be programmed. Here, 'j' is a dummy word line number, and when there are four dummy word lines, it may be an integer of 0≤j≤3.

A situation in which a specific word line (e.g., WL287) and a string selection line SSL<0> are selected for a program operation will be referred to as 'Situation ①'. In 'Situation ①', the control logic circuit 1400 performs a threshold voltage check and/or program operation on the dummy cells connected to the dummy word lines Dum_WL<0>, Dum_WL<1>, Dum_WL<2> and Dum_WL<3> before programming the main memory cells connected to the specific word line WL287 and the string selection line SSL<0>. That is, in 'Situation ①', the threshold voltage status of the dummy cells selected by the string selection line SSL<0> among the dummy cells connected to the dummy word lines Dum_WL<0>, Dum_WL<1>, Dum_WL<2> and Dum_WL<3> may be checked. If the threshold voltage status of the dummy cells is determined to require a program, the program operation on these dummy cells may be performed in units of dummy word lines Dum_WL<0>, Dum_WL<1>, Dum_WL<2> and Dum_WL<3>.

The situation in which a specific word line (e.g., WL287) and a string selection line SSL<1> are selected for the program operation is referred to as '② Situation'. Then, in '② Situation', the control logic circuit 1400 performs a threshold voltage check and/or program operation on the dummy cells connected to the dummy word lines Dum_WL<0>, Dum_WL<1>, Dum_WL<2> and Dum_WL<3> before the program operation on the main memory cells connected to the specific word line WL287 and the string selection line SSL<1>. If the threshold voltage status of the dummy cells is determined to require the program operation, the program operation on these dummy cells may be performed in units of dummy word lines Dum_WL<0>, Dum_WL<1>, Dum_WL<2> and Dum_WL<3>.

In '③ Situation', '④ Situation', '⑤ Situation', and '⑥ Situation' where the specific word line (e.g., WL287) and string selection line SSL<i> are selected, threshold voltage checks and/or program operation on the dummy cells connected to the dummy word lines Dum_WL<j> may be performed, just like in '① Situation' or '② Situation'.

As described above, when a specific word line and string selection line SSL<i> are selected for the program operation, the dummy cells of the corresponding dummy word lines Dum_WL<j> may be checked and/or programmed. And the programming on the main memory cell connected to the specific word line will be performed after the programming on the corresponding dummy cells. Therefore, the time required to threshold voltage check and/or program operation on the dummy cells connected to dummy word lines Dum_WL<j> does not significantly affect the total program time tPROG. On the other hand, the hot electron injection HCI problem caused by negative boosting of the channel during the read recovery operation may be resolved through the dummy word lines Dum_WL<j>.

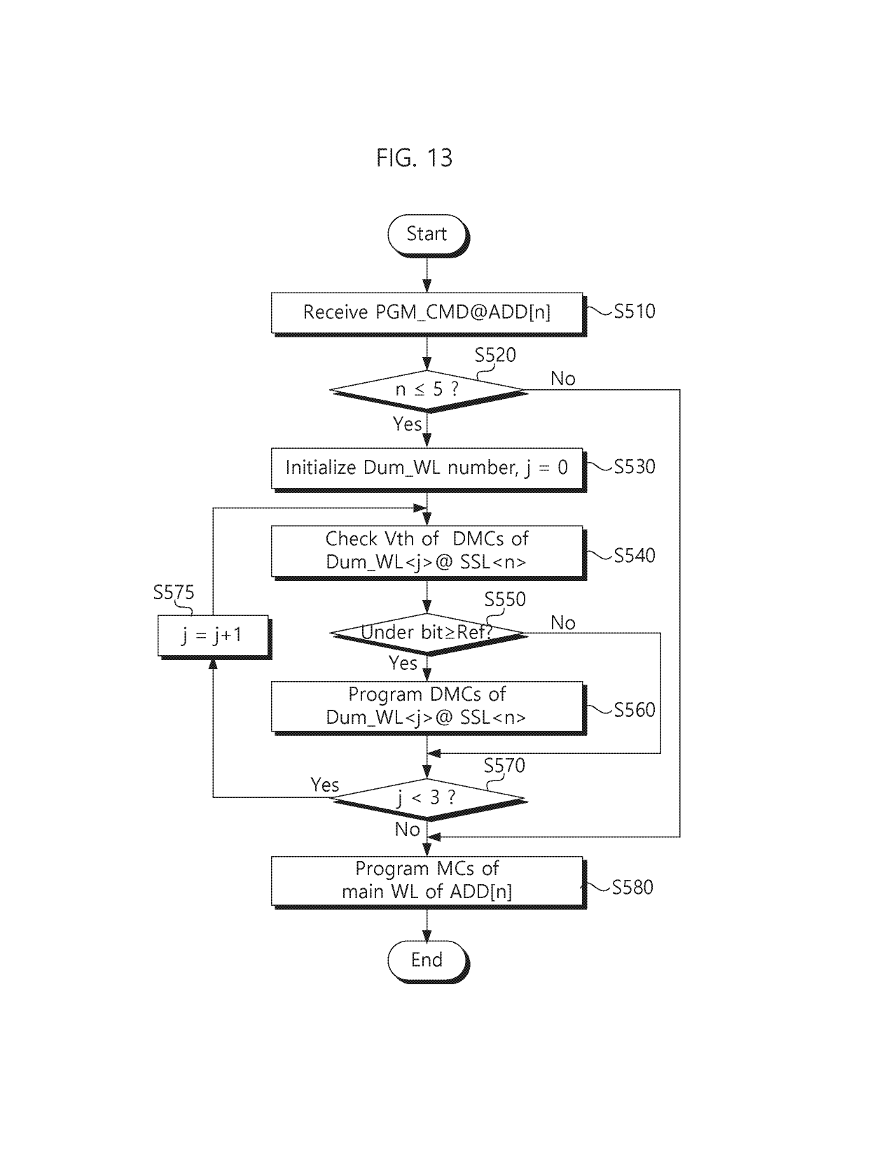

FIG. 13 is a flowchart showing an example of a dummy word line management method according to some implementations. In FIG. 13, threshold voltage check and/or program operation may be performed on memory cells connected to a dummy word line Dum_WL<j> in response to a program command in which a specific word line (e.g., WL287) is selected.

In step S510, the non-volatile memory device 1000 receives a program command PGM_CMD and an address ADD[n].

In step S520, the control logic circuit 1400 determines whether the word line selected through the address ADD[n] corresponds to a specific word line (e.g., the highest word line WL287). In the case of the highest word line, 'n' included in the address will correspond to '0' or more and '5' or less. If the selected word line is a specific word line (or, the highest word line) ('Yes' direction), the procedure moves to step S530. On the other hand, if the selected word line is not a specific word line ('No' direction), the procedure skips to step S580.

In step S530, the control logic circuit 1400 initializes the selection number 'j' of the dummy word line Dum_WL<j> to '0'. That is, the selection number 'j' of the dummy word line Dum_WL<j> for sequentially programming the dummy cells of the dummy word line Dum_WL<j> selected by the string selection line SSL<n> is initialized.

In step S540, the control logic circuit 1400 performs a threshold voltage check operation for dummy cells DMCs selected by the string selection line SSL<n> and connected to the dummy word line (Dum_WL<j>, j=0). The threshold voltage check operation on the dummy cells DMCs connected to the string selection line SSL<n> and the dummy word line Dum_WL<0> may be implemented through reading the dummy cells DMCs. The threshold voltage check operation may be performed by counting the number of dummy cells having the threshold voltage lower than a reference level (hereinafter, under bits) through reading the dummy cells DMCs.

In step S550, the control logic circuit 1400 performs an operation branch according to the threshold voltage check result of the dummy cells DMCs connected to the string selection line SSL<n> and the dummy word line Dum_WL<0>. If the under bit is greater than or equal to the reference value Ref ('Yes' direction), the procedure moves to step S560. On the other hand, if the under bit is less than the reference value Ref ('No' direction), the procedure moves to step S570.

In step S560, the control logic circuit 1400 programs the dummy cells DMCs connected to the string selection line SSL<n> and the dummy word line Dum_WL<0> to the target state, respectively.

In step S570, the control logic circuit 1400 checks whether the selection number 'j' of the dummy word line Dum_WL<j> reaches the final number '3'. If the selection number 'j' of the dummy word line Dum_WL<j> is less than the final number '3' ('Yes' direction), the procedure moves to step S575. On the other hand, if the selection number 'j' of the dummy word line Dum_WL<j> is greater than or equal to the final number '3' ('No' direction), the procedure moves to step S580.

In step S575, the control logic circuit 1400 increases the selection number 'j' of the dummy word line Dum_WL<j>. After that, the procedure returns to step S540 to perform the threshold voltage check operation for the dummy cells DMCs connected to the string selection line SSL<n> and the dummy word line (Dum_WL<1>). Through the operation loops composed of steps S540, S550, S560, S570, and S575, dummy patterns may be sequentially programmed in dummy cells DMCs connected to the string selection line SSL<n> and dummy word lines Dum_WL<0>, Dum_WL<1>, Dum_WL<2>, and Dum_WL<3>.

In step S580, when the programming of the dummy cells of the dummy word line Dum_WL<j> is completed, the programming of the memory cells of the selected main word line (e.g., the highest word line WL287) will be performed.

The above describes the threshold voltage check for the dummy cells of the dummy word line Dum_WL<j> and the programming procedure of the dummy pattern accordingly. The hot electron injection HCI degradation due to negative boosting of the channel may be prevented by the dummy pattern programmed in the dummy cells of the dummy word line Dum_WL<j>.

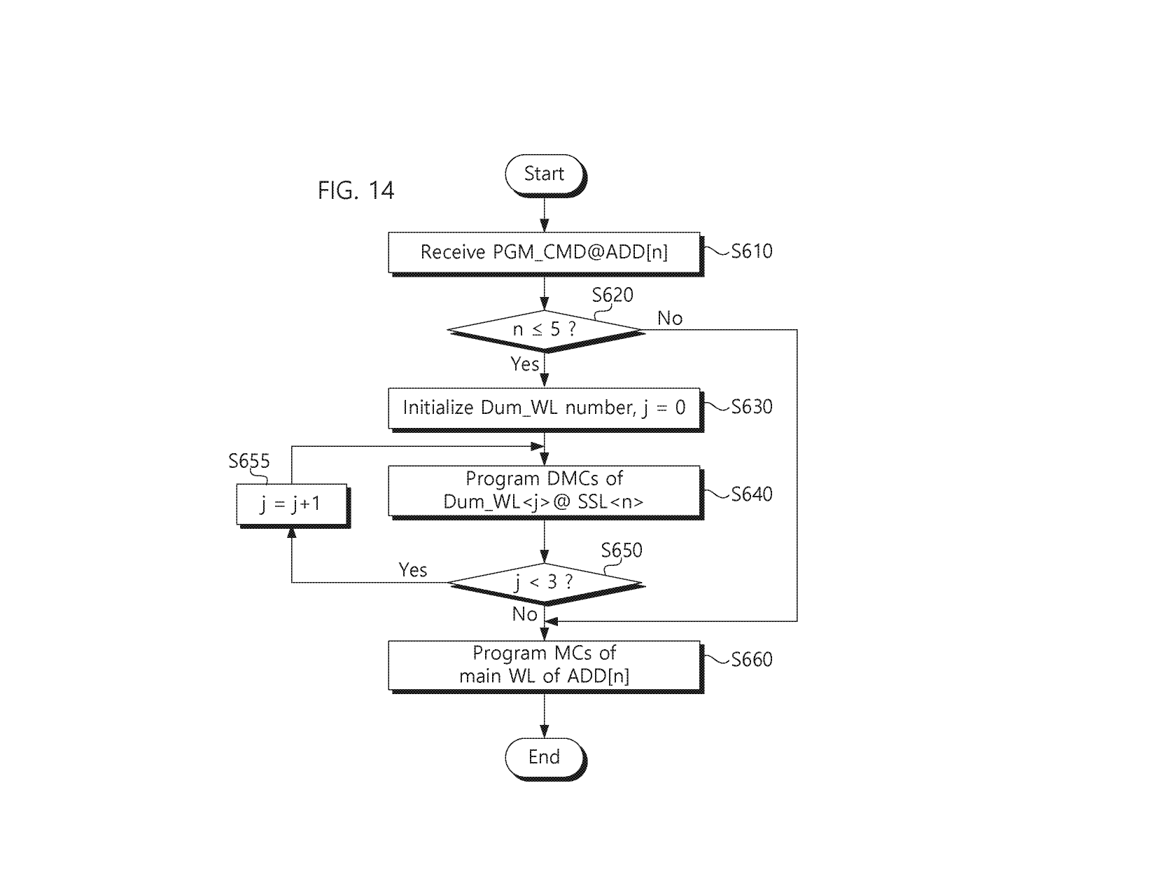

FIG. 14 is a flowchart showing an example of a dummy word line management method according to some implementations. In FIG. 14, all dummy cells of the dummy word line Dum_WL<j> are provided in an erased state by a block erase operation. Therefore, only the program of the dummy cells DMCs connected to the dummy word line Dum_WL<j> may be performed according to a program command in which a specific word line (e.g., WL287) is selected.

In step S610, the non-volatile memory device 1000 receives a program command PGM_CMD and an address ADD[n].

In step S620, the control logic circuit 1400 determines whether the selected word line is a specific word line (e.g., the highest word line WL287) through the address ADD[n]. If the selected word line is the specific word line (or, the highest word line) ('Yes' direction), the procedure moves to step S630. On the other hand, if the selected word line is not the specific word line ('No' direction), the procedure skips to step S660.

In step S630, the control logic circuit 1400 initializes the selection number 'j' of the dummy word line Dum_WL<j> to '0'.

In step S640, the control logic circuit 1400 programs a dummy pattern to dummy cells DMCs connected to the string selection line SSL<n> and the dummy word line Dum_WL<0>.

In step S650, the control logic circuit 1400 checks whether the selection number 'j' of the dummy word line Dum_WL<j> has reached the final number '3'. If the selection number 'j' of the dummy word line Dum_WL<j> is less than the final number '3' ('Yes' direction), the procedure moves to step S655. On the other hand, if the selection number 'j' of the dummy word line Dum_WL<j> is greater than or equal to the final number '3' ('No' direction), the procedure moves to step S660.

In step S655, the control logic circuit 1400 increases the selection number 'j' of the dummy word line Dum_WL<j>. Afterwards, the procedure returns to step S640 to perform the threshold voltage check operation for the dummy cells DMCs connected to the string selection line SSL<n> and the dummy word line Dum_WL<1>. Through the operation loops composed of steps S540, S550, S560, S570, and S575, dummy patterns may be sequentially programmed to dummy cells DMCs connected to the string selection line SSL<n> and dummy word lines Dum_WL<0>, Dum_WL<1>, Dum_WL<2>, and Dum_WL<3>.

In step S660, when the programming of the dummy cells of the dummy word line Dum_WL<j> is completed, the programming of the memory cells of the selected main word line (e.g., the highest word line WL287) will be performed.

The above describes the procedure for programming the dummy pattern to the dummy cells of the dummy word line Dum_WL<j>. Hot electron injection HCI degradation due to negative boosting of the channel may be prevented by a dummy pattern programmed in the dummy cells of the dummy word line Dum_WL<j>.

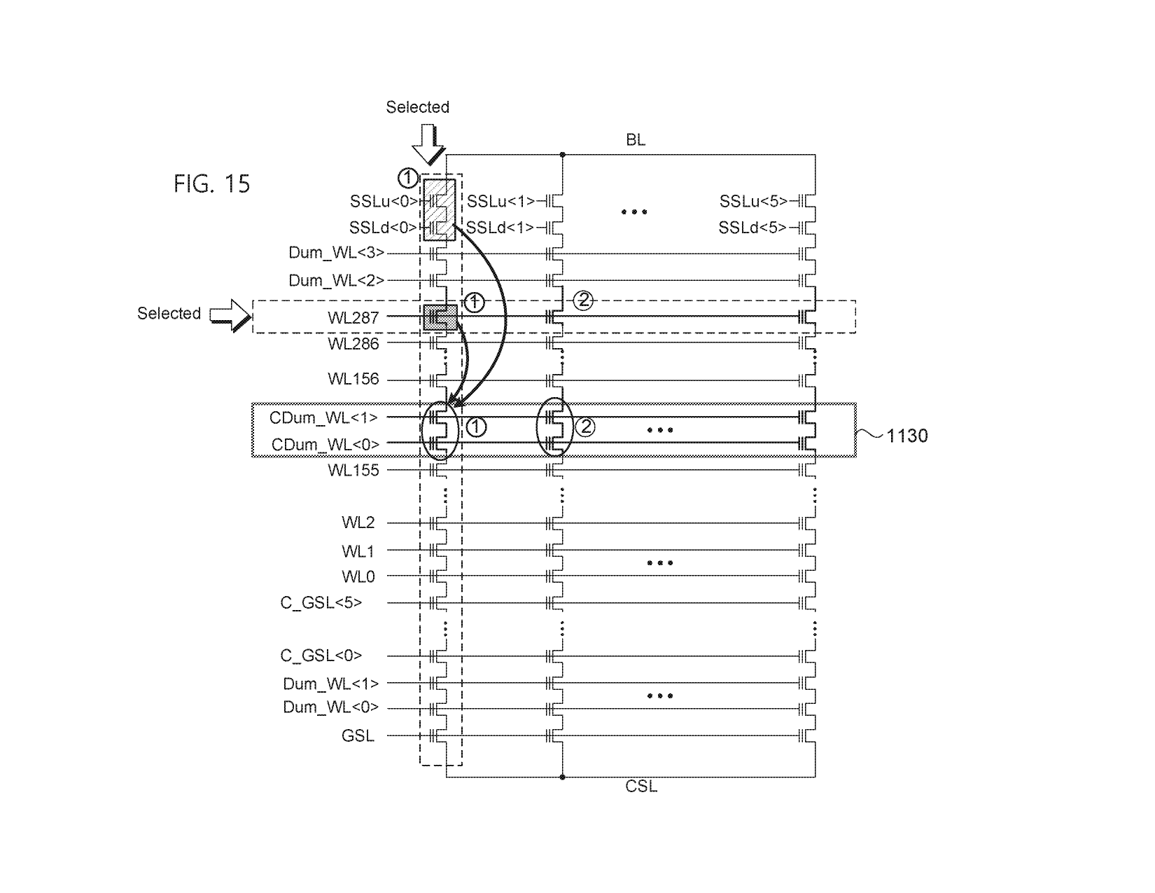

FIG. 15 is a drawing showing an example of a programming method of center dummy word lines that are a type of special function word lines SFWL according to some implementations. In FIG. 15, a center dummy word line 1130 may be located at the center or near the center of a main word line (WL0~WL287). Then, when a specific word line (e.g., WL287) and a string selection line (SSL<i>, an integer of 0≤i≤5) are selected for a program, a corresponding center dummy word line CDum_WL<k> may be programmed. Here, 'k' is a center dummy word line number, and may be '0' or '1' when two center dummy word lines exist.

A situation in which a specific word line (e.g., WL287) and a string selection line SSL<0> are selected for a program is referred to as '① Situation'. Then, in the '① situation', the control logic circuit 1400 performs a threshold voltage check and/or program of the dummy cells connected to each of the center dummy word lines (CDum_WL<0>, CDum_WL<1>) before programming the main memory cells connected to the specific word line WL287 and the string selection line SSL<0>. That is, in the '① situation', the threshold voltage (Vth) status of the dummy cells selected by the string selection line SSL<0> among the dummy cells connected to the center dummy word lines (CDum_WL<0>, CDum_WL<1>) may be checked. If it is determined that the program is necessary based on the threshold voltage check result of the dummy cells, the program for these dummy cells may be performed in units of the center dummy word lines (CDum_WL<0>, CDum_WL<1>).

Let's call a situation in which a specific word line (e.g., WL287) and a string selection line SSL<1> are selected for a program as 'Situation ②'. Then, in 'Situation ②', the control logic circuit 1400 performs a threshold voltage check and/or program of dummy cells connected to each of the center dummy word lines (CDum_WL<0>, CDum_WL<1>) before programming the main memory cells connected to the specific word line WL287 and the string selection line SSL<1>. That is, in 'Situation ②', the threshold voltage (Vth) status of dummy cells selected by the string selection line SSL<1> among the dummy cells connected to the center dummy word lines (CDum_WL<0>, CDum_WL<1>) may be checked. If it is determined that a program is required based on the threshold voltage check result of the dummy cells, the program for these dummy cells may be performed in units of center dummy word lines (CDum_WL<0>, CDum_WL<1>).

In the '③ situation', '④ situation', '⑤ situation', and '⑥ situation' where a specific word line (e.g., WL287) and a string selection line SSL<i> are selected, the check and/or program of the dummy cells connected to the center dummy word lines CDum_WL<k> are performed just like in the '① situation' or '② situation'. In particular, the center dummy word lines CDum_WL<k> are used to increase the local boosting efficiency of the stack unit. Accordingly, the dummy cells of the center dummy word lines CDum_WL<k> only need to be programmed before the word lines (WL0~WL155) of the lower stack are selected for the program. That is, even if a specific word line selected for a program is one of the word lines (WL156 to WL287) of the upper stack, the dummy cells connected to the center dummy word lines CDum_WL<k> may be checked and/or programmed.

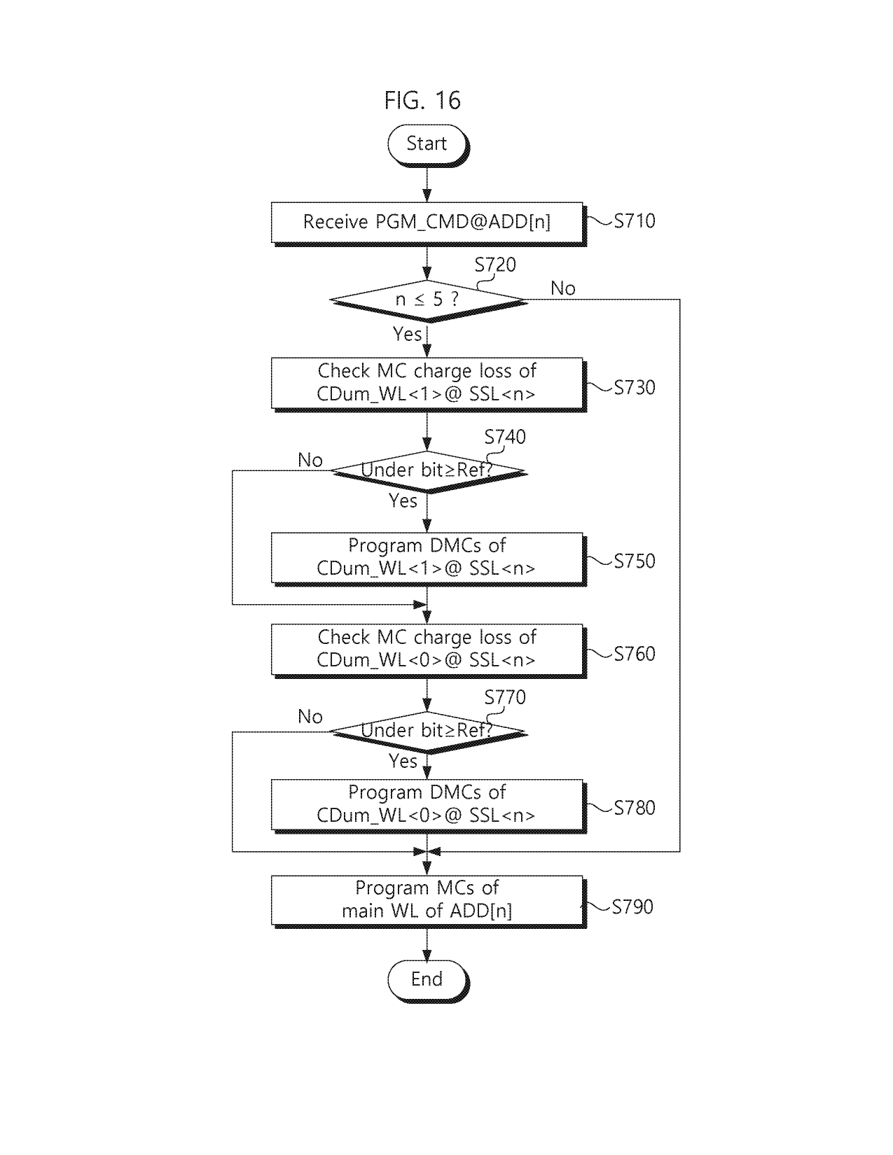

FIG. 16 is a flowchart showing an example of a center dummy word line management method illustrated in FIG. 15 according to some implementations. In FIG. 16, a threshold voltage check and/or program operation may be performed on memory cells connected to the center dummy word lines CDum_WL<k> in response to a program command in which a specific word line (e.g., WL287) is selected.

In step S710, the non-volatile memory device 1000 receives the program command PGM_CMD and an address ADD[n].

In step S720, the control logic circuit 1400 determines whether the selected word line is the specific word line (e.g., the highest word line WL287) through the address ADD[n]. If the selected word line is the specific word line (or the highest word line) ('Yes' direction), the procedure moves to step S730. On the other hand, if the selected word line is not the specific word line ('No' direction), the procedure skips to step S790.

In step S730, the control logic circuit 1400 performs the threshold voltage check operation on the dummy cells DMCs connected to the center dummy word line CDum_WL<1> and selected by the string selection line SSL<n>. The threshold voltage check operation may be performed by counting the number of dummy cells (under bits) having a threshold voltage lower than a reference level by reading the dummy cells DMCs.

In step S740, the control logic circuit 1400 performs an operation branch according to the result of the threshold voltage check operation on the dummy cells DMCs connected to the string selection line SSL<n> and the center dummy word line CDum_WL<1>. If the under bit is greater than or equal to the reference value Ref ('Yes' direction), the procedure moves to step S750. On the other hand, if the under bit is less than the reference value Ref ('No' direction), the procedure skips to step S760.

In step S750, the control logic circuit 1400 programs the dummy cells DMCs connected to the string selection line SSL<n> and the center dummy word line CDum_WL<1> with a designated dummy pattern.

In step S760, the control logic circuit 1400 performs the threshold voltage check operation on the dummy cells DMCs connected to the center dummy word line CDum_WL<0> and selected by the string selection line SSL<n>.

In step S770, the control logic circuit 1400 performs an operation branch according to the threshold voltage check result of the dummy cells DMCs connected to the string selection line SSL<n> and the center dummy word line CDum_WL<0>. If the under bit is greater than or equal to the reference value Ref ('Yes' direction), the procedure moves to step S780. On the other hand, if the under bit is less than the reference value Ref ('No' direction), the procedure skips to step S790.

In step S780, the control logic circuit 1400 programs the dummy cells DMCs connected to the string selection line SSL<n> and the center dummy word line CDum_WL<0> with a designated dummy pattern.

In step S790, after the program of the dummy cells of the center dummy word lines CDum_WL<0> and CDum_WL<1> is completed, the program operation will be performed on the memory cells of the selected main word line (e.g., the top word line WL287).

The above describes the threshold voltage check and the dummy pattern program procedure for the dummy cells of the center dummy word line CDum_WL<k>. The local boosting efficiency of the stack unit channel may be improved by the dummy pattern programmed on the dummy cells of the center dummy word line CDum_WL<k>.

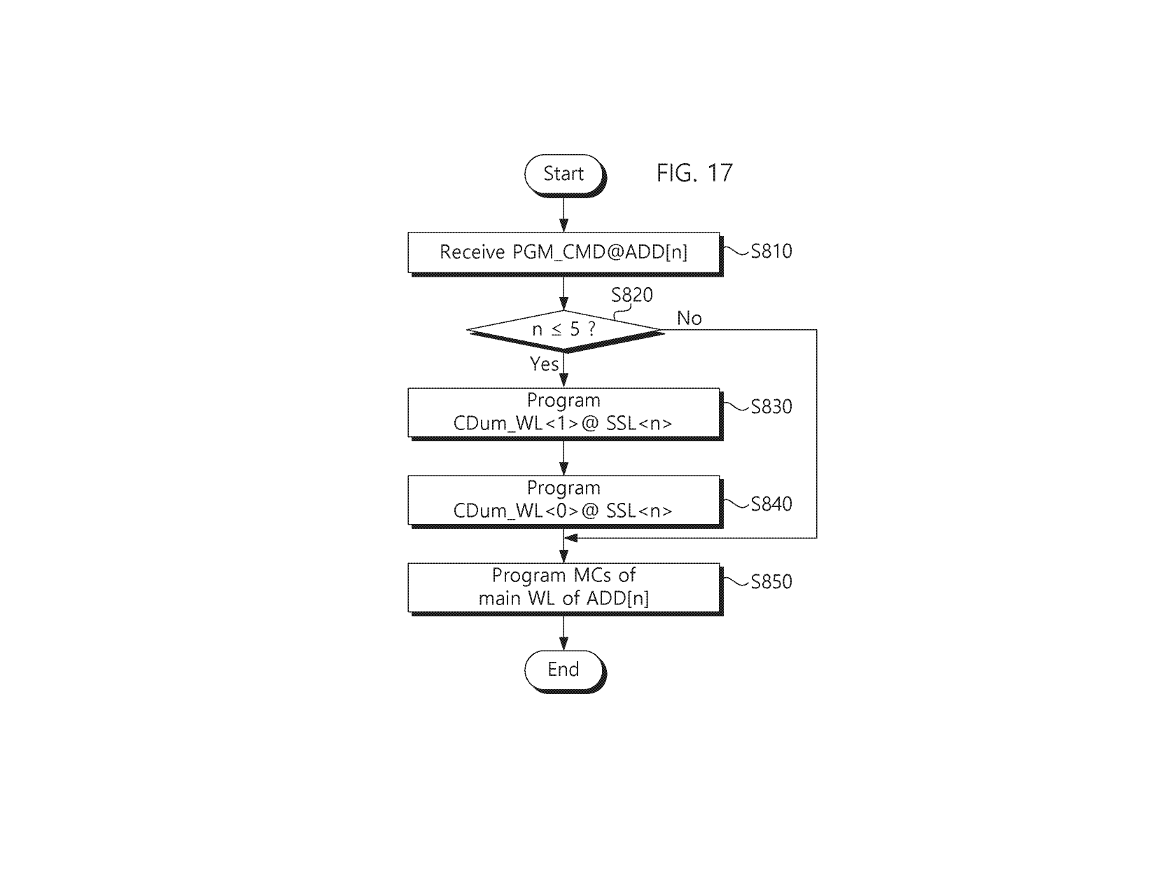

FIG. 17 is a flowchart showing an example of a center dummy word line management method shown in FIG. 15 according to some implementations. In FIG. 17, memory cells connected to the center dummy word line CDum_WL<k> may be programmed with a dummy pattern without checking the threshold voltage.

In step S810, the non-volatile memory device 1000 receives a program command PGM_CMD and an address ADD[n].

In step S820, the control logic circuit 1400 determines whether the selected word line is a specific word line (e.g., the highest word line WL287) through the address ADD[n]. If the selected word line is the specific word line (or, the highest word line) ('Yes' direction), the procedure moves to step S830. On the other hand, if the selected word line is not the specific word line ('No' direction), the procedure skips to step S850.

In step S830, the control logic circuit 1400 programs a dummy pattern in dummy cells DMCs connected to the center dummy word line CDum_WL<1> and selected by the string selection line SSL<n>.

In step S840, the control logic circuit 1400 programs the dummy cells DMCs connected to the string selection line SSL<n> and the center dummy word line CDum_WL<0> with a designated dummy pattern.

In step S850, when the program operation on the dummy cells of the center dummy word lines CDum_WL<0> and CDum_WL<1> is completed, the program operation will be performed on the memory cells of the selected main word line (e.g., the highest word line WL287).

The above describes a program procedure without threshold voltage check of the dummy cells of the center dummy word line CDum_WL<k>. The local boosting efficiency of the stack unit channel may be improved by the dummy pattern programmed in the dummy cells of the center dummy word line CDum_WL<k>.

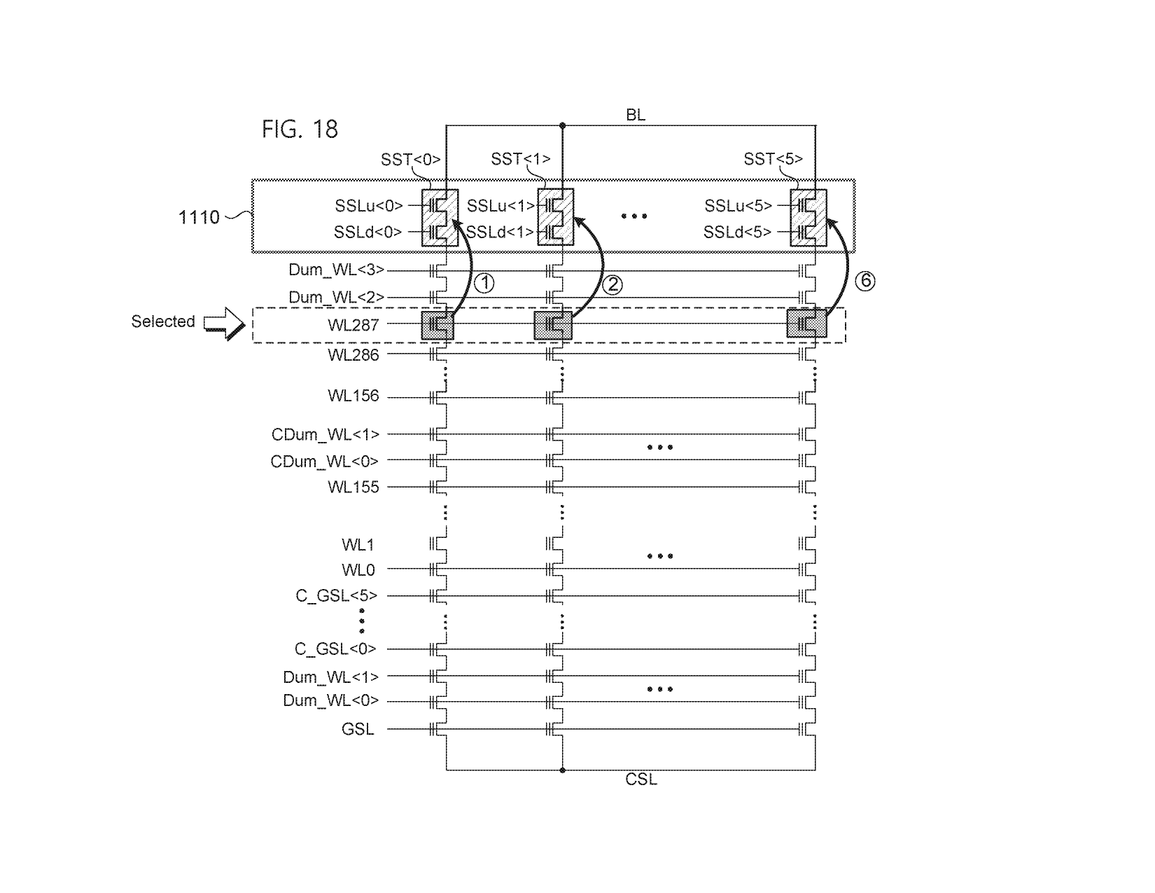

FIG. 18 is a diagram showing an example of a management method of a programmable string selection line SSL that is one of the special function word lines SFWL according to some implementations. In FIG. 18, the programmable string selection line 1110 may be located above the dummy word line Dum_WL<3>. Then, when a specific word line (e.g., WL287) and a string selection line (SSL<i>, an integer of 0≤i≤5) are selected for the program, the corresponding programmable string selection line SSL<i> may be programmed.

The situation in which the specific word line (e.g., WL287) and the string selection line SSL<0> are selected for the program will be referred to as '① Situation'. Then, in the '① situation', the control logic circuit 1400 performs a threshold voltage check and/or a program operation on the string selection transistors SST<0> connected to the string selection line SSL<0> before programming the main memory cells connected to the specific word line WL287 and the string selection line SSL<0>. In other words, in the '① situation', the threshold voltage state of the string selection transistors SST<0> connected to the string selection line SSL<0> may be checked. If it is determined that a program operation is necessary based on the threshold voltage check result of the string selection transistors SST<0>, the program operation on the string selection transistors SST<0> may be performed.

The situation in which the specific word line (e.g., WL287) and the string selection line SSL<1> are selected for the program will be referred to as the '② situation'. Then, in the '② situation', the control logic circuit 1400 performs the threshold voltage check and/or the program operation on the string selection transistors SST<1> connected to the specific word line WL287 and the string selection line SSL<1>. That is, in the '② situation', the threshold voltage state of the string selection transistors SST<1> connected to the string selection line SSL<1> may be checked. If it is determined that the program operation is necessary based on the threshold voltage check result of the string selection transistors SST<1>, the program operation on the string selection transistors SST<1> may be performed.

In the '③ situation', '④ situation', '⑤ situation', and '⑥ situation' where the specific word line (e.g., WL287) and a string selection line SSL<i> are selected, the threshold voltage check and/or program operation on the string selection transistors SST<i> are performed just like in the '① situation' or '② situation'. During block erase, the erasure of the string selection transistors SST<i> is blocked. Therefore, the string selection transistors SST<i> should not be programmed directly without the threshold voltage check operation.

Here, it may be considered that the memory cells of the main word line are programmed while only the string select transistors SST<0> are programmed. The string select voltage (e.g., VDD) will be provided to the string selection line SSL<0>, and 0V will be provided to the unselected string selection lines SSL<1> to SSL<5> that are not yet programmed. During the program execution section, the string selection transistors SST<0> will be turned on by the string select voltage VDD. On the other hand, the string selection transistors SST<1> to SST<5> of the unselected string selection lines SSL<1> to SSL<5> may sufficiently maintain the turn-off state because they have not been erased before, even before the program. Accordingly, there is no need to program all the string selection transistors (SST<0> to SST<5>) at once.

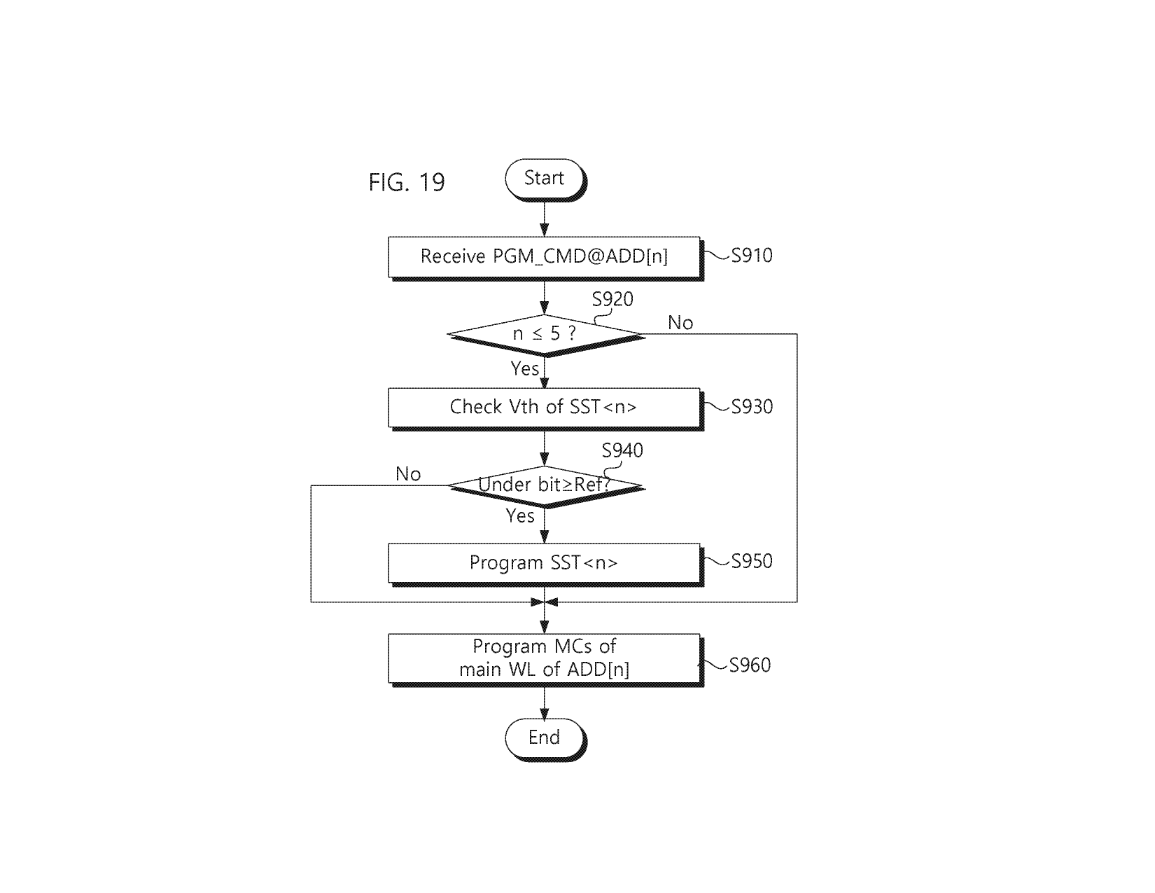

FIG. 19 is a flowchart showing an example of a method of managing a string selection line of FIG. 18 according to some implementations. In FIG. 19, when a specific word line (e.g., WL287) and a string selection line (SSL<n>, an integer of 0≤n≤5) are selected, a threshold voltage check and/or a program operation on the corresponding string selection transistors SST<n> may be performed.

In step S910, the non-volatile memory device 1000 receives a program command PGM_CMD and an address ADD[n].

In step S920, the control logic circuit 1400 determines whether the selected word line is the specific word line (e.g., the highest word line WL287) through the address ADD[n]. If the selected word line is the specific word line (or, the highest word line) ('Yes' direction), the procedure moves to step S930. On the other hand, if the selected word line is not the specific word line ('No' direction), the procedure skips to step S960.

In step S930, the control logic circuit 1400 performs a threshold voltage check operation on the string selection transistors SST<n> connected to the string selection line SSL<n>. The threshold voltage check operation may be performed by counting the number of string selection transistors (under bits) having the threshold voltage lower than a reference level by reading the string selection transistors SST<n>.

In step S940, the control logic circuit 1400 performs an operation branch according to the threshold voltage check result for the string selection transistors SST<n>. If the under bit is higher than the reference value Ref ('Yes' direction), the procedure moves to step S950. On the other hand, if the under bit is less than the reference value Ref ('No' direction), the procedure moves to step S960.

In step S950, the control logic circuit 1400 programs the string selection transistors SST<n> to the target state, respectively.

In step S960, when the string selection transistors SST<n> are programmed, the memory cells of the selected main word line (e.g., the highest word line WL287) will be programmed.

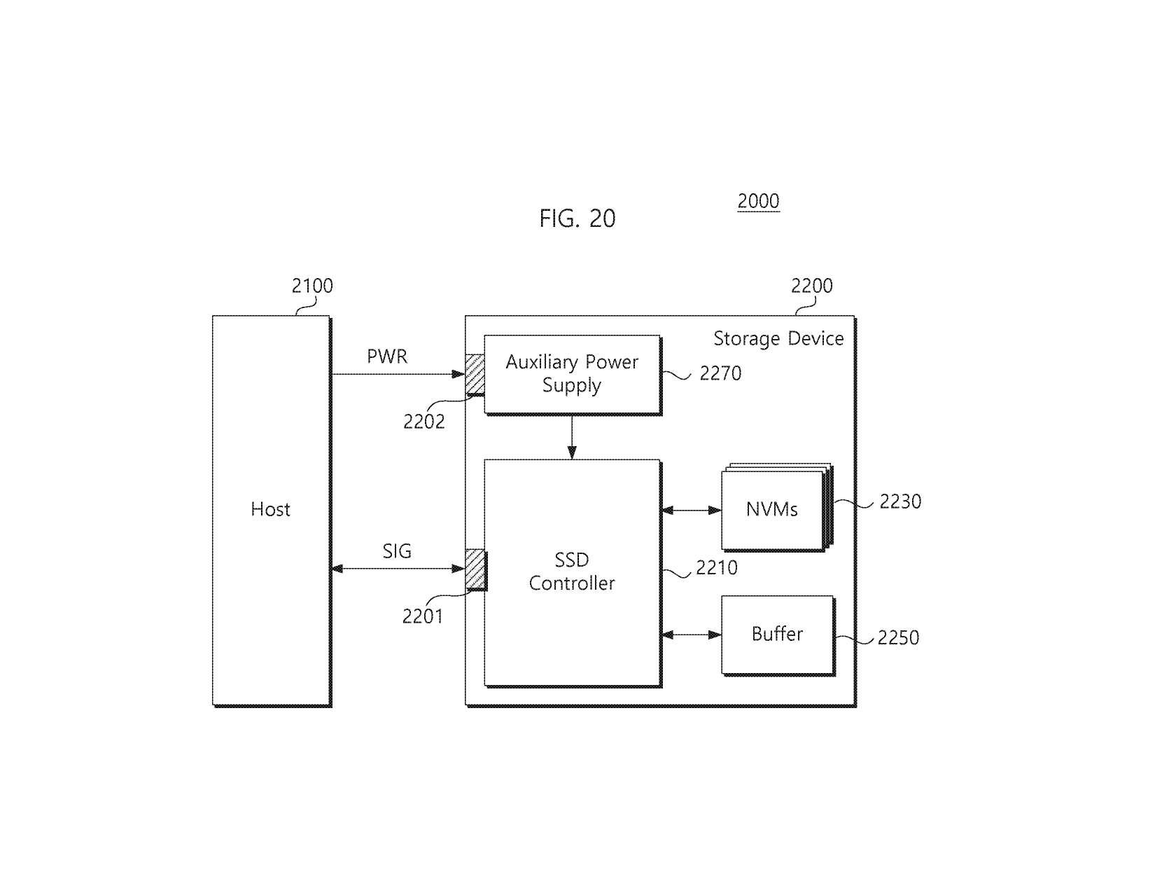

FIG. 20 is a block diagram showing an example of a storage system including a non-volatile memory device according to some implementations. In FIG. 20, the storage system 2000 includes a host 2100 and a storage device 2200 implemented as a solid state drive. In an exemplary embodiment, the storage device 2200 may include a plurality of non-volatile memories 2230 described with reference to FIGS. 1 to 19.

The storage device 2200 exchanges signals SIG with the host 2100 through the signal connector 2201 and receives power PWR through the power connector 2202. The storage device 2200 includes an SSD controller 2210, a plurality of non-volatile memories 2230, a buffer memory 2240, and an auxiliary power supply 2270.

The SSD controller 2210 may control the plurality of non-volatile memories 2230 in response to a signal SIG received from the host 2100. The plurality of non-volatile memories 2230 may operate under the control of the SSD controller 2210. The auxiliary power supply 2270 is connected to the host 2100 through the power connector 2202. The auxiliary power supply 2270 may receive power PWR from the host 2100 and charge it. The auxiliary power supply 2270 may provide power to the storage device 2200 when the power supply from the host 2100 is not smooth. The buffer memory 2250 may be used as a buffer memory of the storage device 2200.

In some implementations, each of the plurality of non-volatile memories 2230 may efficiently perform management operations for special function word lines Coded GSL, SSL, Dummy WL and CDummy WL in which user data is not stored. High data reliability may be maintained without performance degradation through the management operations of the special function word lines Coded GSL, SSL, Dummy WL and CDummy WL.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A method for managing a special function word line of a non-volatile memory device, comprising:
selecting, using at least one circuit of the non-volatile memory device, memory cells according to a program command;
based on the memory cells corresponding to a specific word line, determining, using the at least one circuit, a threshold voltage level of special function memory cells connected to the special function word line;
programming, by the at least one circuit, the special function memory cells with a predetermined pattern based on determining the threshold voltage level; and
programming, by the at least one circuit, the memory cells selected according to the program command.

2. The method of claim 1,
wherein the special function word line corresponds to a coded ground selection line, and
wherein the method comprises:
programing the special function memory cells with the predetermined pattern differently according to a layer corresponding to string selection lines.

3. The method of claim 2, comprising:
programming the special function memory cells with the predetermined pattern based on a number of under bits being greater than or equal to a reference value, the under bits having a threshold voltage level that is lower than a target level among the special function memory cells.

4. The method of claim 3, comprising:
based on the number of under bits being less than the reference value, omitting programming of the special function memory cells with the predetermined pattern.

5. The method of claim 1, wherein the specific word line corresponds to a word line having a highest program priority among main word lines.

6. The method of claim 1, wherein the special function word line includes at least one of a programmable string select line, a dummy word line, or a center dummy word line.

7. The method of claim 6, comprising:
programming the special function memory cells connected to the center dummy word line based on the specific word line being selected from a top of the center dummy word line.

8. A non-volatile memory device comprising:
a cell array having a main word line and a special function word line, the main word line connecting to main memory cells storing data, and the special function word line connecting to special function memory cells supporting a selection operation of the main memory cells;
a row decoder configured to select the main word line or the special function word line in response to an address;
a page buffer connected to the main memory cells or the special function memory cells through a bit line; and
a control logic circuit configured to perform at least one of:
determining a threshold voltage level of the special function memory cells in response to selection of a specific word line by a program command, or
controlling at least one of the row decoder or the page buffer to program the special function memory cells with a predetermined pattern.

9. The device of claim 8, wherein the special function memory cells are configured to be erased during a block erase operation.

10. The device of claim 9, wherein the special function memory cells are configured to be programmed with the predetermined pattern without determining the threshold voltage level in response to selection of the specific word line.

11. The device of claim 8, wherein the control logic circuit is configured to program the special function memory cells with the predetermined pattern based on determining the threshold voltage level.

12. The device of claim 8,
wherein the special function word line corresponds to a coded ground selection line, and
wherein the control logic circuit is configured to program the special function memory cells with the predetermined pattern differently according to a layer corresponding to string selection lines.

13. The device of claim 8, wherein the special function word line includes at least one of a programmable string selection line, a dummy word line, or a center dummy word line.

14. The device of claim 13, wherein the control logic circuit is configured to program the special function memory cells connected to the center dummy word line based on the specific word line being located at a top of the center dummy word line.

15. The device of claim 9, wherein the specific word line corresponds to a word line having a highest program priority among a plurality of main word lines.

16. A method for managing a non-volatile memory device, comprising:
erasing, using at least one circuit of the non-volatile memory device, special function memory cells connected to a special function word line during a block erase operation;
selecting, using the at least one circuit, memory cells according to a program command;
programming, using the at least one circuit, the special function memory cells with a predetermined pattern based on the memory cells corresponding to a specific word line; and
programming, using the at least one circuit, data requested to be written to the memory cells.

17. The method of claim 16,
wherein the special function word line corresponds to a coded ground selection line, and
wherein the method comprises:
programming the special function memory cells with the predetermined pattern differently according to a layer corresponding to string selection lines.

18. The method of claim 17,
wherein the coded ground selection line includes a plurality of coded ground selection lines corresponding to a number of the string selection lines, and
wherein, the method comprises:
based on a string selection line being selected in the specific word line, programming the special function memory cells with the predetermined pattern, the special function memory cells being connected to one of the plurality of coded ground selection lines.

19. The method of claim 16, wherein the specific word line corresponds to one of main word lines having a highest program priority in which data is stored.

20. The method of claim 19, wherein the special function word line includes at least one of a dummy word line or a center dummy word line.
